(19) United States
(12) Patent Application Publication
(10) Pub. No.: US 2021/0013219 A1
(43) Pub. Date: Jan. 14, 2021

(54) SEMICONDUCTOR STORAGE DEVICE AND MULTIPLIER-ACCUMULATOR

(71) Applicant: SONY SEMICONDUCTOR SOLUTIONS CORPORATION, Kanagawa (JP)

(72) Inventors: Jun OKUNO, Kanagawa (JP); Fumitaka SUGAYA, Kanagawa (JP); Masanori TSUKAMOTO, Kanagawa (JP)

(73) Assignee: SONY SEMICONDUCTOR SOLUTIONS CORPORATION, Kanagawa (JP)

(21) Appl. No.: 16/981,319

(22) PCT Filed: Mar. 12, 2019
(86) PCT No.: PCT/JP2019/009982

§ 371 Date: Sep. 16, 2020

(30) Foreign Application Priority Data
Mar. 30, 2018 (JP) 2018-067780

(51) Int. Cl. H01L 27/11507; H01L 27/11504; H01L 27/108; H01L 29/423

(52) U.S. Cl. CPC H01L 27/11507; H01L 29/42356; H01L 27/10826; H01L 27/11504

(57) ABSTRACT

A semiconductor storage device and a multiplier-accumulator are provided that are capable of applying a sufficient voltage to a ferroelectric capacitor and are suitable for high integration. A semiconductor storage device includes: a transistor; and a ferroelectric capacitor that is formed by sandwiching a ferroelectric material between a pair of conductive materials, one of the pair of conductive materials being electrically connected to a gate electrode of the transistor, in which a channel of the transistor is three-dimensionally formed over a plurality of surfaces.

### TECHNICAL FIELD

The present disclosure relates to a semiconductor storage device and a multiplier-accumulator.

### BACKGROUND ART

In recent years, a ferroelectric random access memory (FeRAM) has been attracting attention as a next-generation memory. The FeRAM is a semiconductor storage device that stores information by using a direction of residual polarization of ferroelectrics.

As one example of a structure of the FeRAM, a structure is known in which a ferroelectric capacitor is formed by sequentially stacking a lower electrode, a ferroelectric film, and an upper electrode on a gate electrode of a metal-insulator-semiconductor (MIS) field effect transistor that has been formed on a semiconductor substrate. Such a structure is also referred to as a metal-ferroelectric-metal-insulator-semiconductor (MFMIS) structure.

In an FeRAM having an MFMIS structure, a voltage is applied between the semiconductor substrate and the upper electrode, and therefore the applied voltage is distributed to a gate insulating film of the MIS field effect transistor and the ferroelectric film of the ferroelectric capacitor. Therefore, in some cases, a voltage that is sufficient to reverse the polarization of the ferroelectric film has failed to be applied to the ferroelectric film depending on a ratio of the gate capacitance of the MIS field effect transistor and the capacitance of the ferroelectric capacitor.

For example, Patent Document 1 described below discloses a technology for increasing a distributed voltage of a ferroelectric capacitor by further providing a paraelectric capacitor in which one end is connected between a gate electrode of an MIS field effect transistor and a lower electrode of the ferroelectric capacitor and the other end is connected to a source of the MIS field effect transistor in an FeRAM having an MFMIS structure.

### CITATION LIST

### Patent Document

Patent Document 1: Japanese Patent Application Laid-Open No. 2004-22944

### SUMMARY OF THE INVENTION

### Problems To Be Solved By The Invention

However, in the technology disclosed in Patent Document 1 described above, a region where the paraelectric capacitor is formed needs to be further provided on a semiconductor substrate, and therefore an area per unit cell of the FeRAM increases. Therefore, it has been difficult to highly integrate the FeRAM disclosed in Patent Document 1.

Accordingly, the present disclosure proposes novel and improved semiconductor storage device and multiplier-accumulator that are capable of applying a sufficient voltage to a ferroelectric capacitor and have a structure suitable for high integration.

### Solutions to Problems

According to the present disclosure, a semiconductor storage device is provided that includes: a transistor; and a ferroelectric capacitor that is formed by sandwiching a ferroelectric material between a pair of conductive materials, one of the pair of conductive materials being electrically connected to a gate electrode of the transistor, in which a channel of the transistor is three-dimensionally formed over a plurality of surfaces.

Furthermore, according to the present disclosure, a multiplier-accumulator is provided that includes: a transistor; and a ferroelectric capacitor that is formed by sandwiching a ferroelectric material between a pair of conductive materials, one of the pair of conductive materials being electrically connected to a gate electrode of the transistor, in which a channel of the transistor is three-dimensionally formed over a plurality of surfaces.

Furthermore, according to the present disclosure, a semiconductor storage device is provided that includes: a transistor; and a ferroelectric capacitor that is formed by sandwiching a ferroelectric material between a pair of conductive materials, one of the pair of conductive materials being electrically connected to a gate electrode of the transistor, in which the pair of conductive materials and the ferroelectric material are stacked to be parallel to an upper surface of the gate electrode, to provide the ferroelectric capacitor on the gate electrode, and a planar area of the ferroelectric capacitor is smaller than a planar area of the upper surface of the gate electrode.

Moreover, according to the present disclosure, a multiplier-accumulator is provided that includes: a transistor; and a ferroelectric capacitor that is formed by sandwiching a ferroelectric material between a pair of conductive materials, one of the pair of conductive materials being electrically connected to a gate electrode of the transistor, in which the pair of conductive materials and the ferroelectric material are stacked to be parallel to an upper surface of the gate electrode, to provide the ferroelectric capacitor on the gate electrode, and a planar area of the ferroelectric capacitor is smaller than a planar area of the upper surface of the gate electrode.

According to the present disclosure, a semiconductor storage device can further increase a distributed voltage to be applied to a ferroelectric film of a ferroelectric capacitor, by increasing the gate capacitance of a field effect transistor without an increase in the size of a unit cell.

### Effects of the Invention

As described above, according to the present disclosure, a semiconductor storage device and a multiplier-accumulator can be provided that are capable of applying a sufficient voltage to a ferroelectric capacitor and have a structure suitable for high integration.

Note that the effect described above is not necessarily restrictive, and any of the effects described in the description or other effects that can be grasped from the description may be exhibited in addition to the effect described above or instead of the effect described above.

### BRIEF DESCRIPTION OF DRAWINGS

FIG. 1 is a longitudinal sectional view schematically illustrating a structure example of a semiconductor storage device according to a first embodiment of the present disclosure.

FIG. 2A is a longitudinal sectional view schematically illustrating a structure in a variation of the semiconductor storage device.

FIG. 2B is a longitudinal sectional view schematically illustrating a structure in a variation of the semiconductor storage device.

FIG. 3 is a longitudinal sectional view that defines the dimensions of each configuration of the semiconductor storage device illustrated in FIG. 1.

FIG. 4A is a graph illustrating a range that causes the semiconductor storage device according to the same embodiment to have satisfactory characteristics.

FIG. 4B is a graph illustrating a range that causes the semiconductor storage device according to the same embodiment to have satisfactory characteristics.

FIG. 4C is a graph illustrating a range that causes the semiconductor storage device according to the same embodiment to have satisfactory characteristics.

FIG. 5A is a schematic longitudinal sectional view illustrating one process of a manufacturing method of the semiconductor storage device according to the same embodiment.

FIG. 5B is a schematic longitudinal sectional view illustrating one process of the manufacturing method of the semiconductor storage device according to the same embodiment.

FIG. 5C is a schematic longitudinal sectional view illustrating one process of the manufacturing method of the semiconductor storage device according to the same embodiment.

FIG. 5D is a schematic longitudinal sectional view illustrating one process of the manufacturing method of the semiconductor storage device according to the same embodiment.

FIG. 5E is a schematic longitudinal sectional view illustrating one process of the manufacturing method of the semiconductor storage device according to the same embodiment.

FIG. 5F is a schematic longitudinal sectional view illustrating one process of the manufacturing method of the semiconductor storage device according to the same embodiment.

FIG. 5G is a schematic longitudinal sectional view illustrating one process of the manufacturing method of the semiconductor storage device according to the same embodiment.

FIG. 6 is a plan view schematically illustrating a planar configuration of a semiconductor device in which a plurality of the semiconductor storage devices according to the same embodiment is arranged in a matrix shape.

FIG. 7 is a longitudinal sectional view schematically illustrating a section that is taken along line A-AA of the semiconductor device illustrated in FIG.

6.

FIG. 8 is an equivalent circuit diagram of the semiconductor device illustrated in FIGS. 6 and 7.

FIG. 9 is a longitudinal sectional view schematically illustrating a sectional structure in a variation of the semiconductor device.

FIG. 10 is a perspective view schematically illustrating a structure example of a semiconductor storage device according to a second embodiment of the present disclosure.

FIG. 11A is a longitudinal sectional view schematically illustrating a structure in a variation of the semiconductor storage device.

FIG. 11B is a longitudinal sectional view schematically illustrating a structure in a variation of the semiconductor storage device.

FIG. 11C is a longitudinal sectional view schematically illustrating a structure in a variation of the semiconductor storage device.

FIG. 11D is a longitudinal sectional view schematically illustrating a structure in a variation of the semiconductor storage device.

FIG. 12 is a perspective view that defines the dimensions of each configuration of the semiconductor storage device illustrated in FIG. 10.

FIG. 13 is a plan view schematically illustrating a planar configuration of a semiconductor device in which a plurality of the semiconductor storage devices according to the same embodiment is arranged in a matrix shape.

FIG. 14 is a longitudinal sectional view schematically illustrating a structure example of a semiconductor storage device according to the same embodiment.

FIG. 15 is a longitudinal sectional view that defines the dimensions of each configuration of the semiconductor storage device illustrated in FIG. 14.

FIG. 16A is a schematic longitudinal sectional view illustrating one process of a manufacturing method of the semiconductor storage device according to the same embodiment.

FIG. 16B is a schematic longitudinal sectional view illustrating one process of the manufacturing method of the semiconductor storage device according to the same embodiment.

FIG. 16C is a schematic longitudinal sectional view illustrating one process of the manufacturing method of the semiconductor storage device according to the same embodiment.

FIG. 16D is a schematic longitudinal sectional view illustrating one process of the manufacturing method of the semiconductor storage device according to the same embodiment.

FIG. 16E is a schematic longitudinal sectional view illustrating one process of the manufacturing method of the semiconductor storage device according to the same embodiment.

FIG. 17 is a longitudinal sectional view schematically illustrating a structure in a variation of the semiconductor storage device.

FIG. 18 is a longitudinal sectional view schematically illustrating a structure in a variation of the semiconductor storage device.

FIG. 19 is a longitudinal sectional view schematically illustrating a structure in a variation of the semiconductor storage device.

### MODE FOR CARRYING OUT THE INVENTION

Preferred embodiments of the present disclosure are described in detail below with reference to the attached drawings. Note that, in the description and the drawings, components that have substantially the same functional configuration are denoted by the same reference sign, and therefore a duplicate description is omitted.

In each drawing that is referred to in the description below, in some cases, the sizes of some constituent members are emphasized and illustrated for convenience of description. Accordingly, the relative sizes of constituent members illustrated in each of the drawings do not always accurately indicate an actual size relationship among the constituent members. Furthermore, in the description below, a direction in which substrates or layers are stacked is described as an upward direction in some cases.

Note that description is provided in the order described below.

1. First embodiment

1.1. Structure examples

1.2. Design example

1.3. Manufacturing method

1.4. Application examples

2. Second embodiment

2.1. Structure examples

2.2. Design example

2.3. Application example

3. Third embodiment

3.1. Structure example

3.2. Design example

3.3. Manufacturing method

3.4. Variations

### 1. First Embodiment

(1.1. Structure Examples)

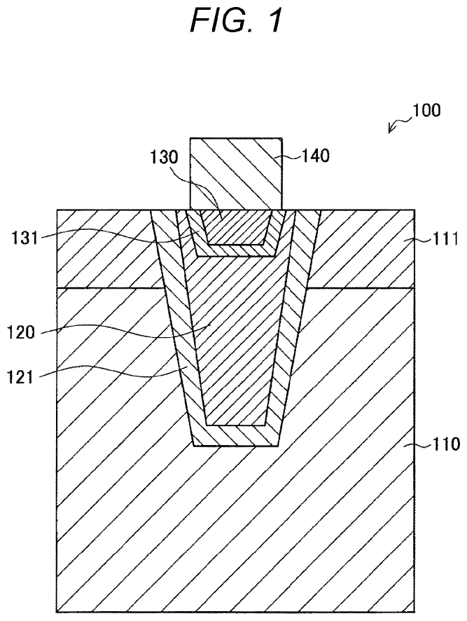

First, a structure example of a semiconductor storage device according to a first embodiment of the present disclosure is described with reference to FIG. 1. FIG. 1 is a longitudinal sectional view schematically illustrating a structure example of a semiconductor storage device according to the present embodiment.

As illustrated in FIG. 1, a semiconductor storage device 100 includes a semiconductor substrate 110, source or drain regions 111, a gate insulating film 121, a lower electrode 120, a ferroelectric film 131, an upper electrode 130, and a conductor electrode 140.

The semiconductor storage device 100 is an FeRAM that has an MFMIS structure in which a ferroelectric capacitor is connected in series on a gate electrode of a field effect transistor. Specifically, the field effect transistor includes the semiconductor substrate 110, the source or drain regions 111, the gate insulating film 121, and the lower electrode 120, and the ferroelectric capacitor includes the lower electrode 120, the ferroelectric film 131, and the upper electrode 130. The ferroelectric capacitor is connected in series to a gate of the field effect transistor by the lower electrode 120.

The semiconductor substrate 110 is a substrate that is configured by using a semiconductor material. A first conductive type impurity (for example, a p-type impurity such as boron or aluminum) has been introduced into the semiconductor substrate 110 in a region where the semiconductor storage device 100 is formed. The semiconductor substrate 110 may be a silicon substrate, or may be a silicon on insulator (SOI) substrate in which an insulating film of SiO₂ or the like is held in the silicon substrate. Alternatively, the semiconductor substrate 110 may be a substrate that includes another elemental semiconductor such as germanium or a substrate that includes a compound semiconductor such as gallium arsenide (GaAs), gallium nitride (GaN), or silicon carbide (SiC). Moreover, the semiconductor substrate 110 may be a substrate in which a semiconductor layer has been stacked on a substrate including quartz, sapphire, resin, metal, or the like.

The source or drain regions 111 are second conductive type regions (for example, n-type regions) that have been formed in the semiconductor substrate 110. Specifically, the source or drain regions 111 are provided by introducing a second conductive type impurity (for example, an n-type impurity such as phosphorus or arsenic) into regions on both sides of an opening provided in the semiconductor substrate 110. Inside the opening provided in the semiconductor substrate 110, a field effect transistor and a ferroelectric capacitor is formed. Note that the source or drain regions 111 do not always need to be provided on both sides of the opening provided in the semiconductor substrate 110, if the source or drain regions 111 are separated from each other.

Note that, from among the source or drain regions 111 that have been formed on both sides of the opening provided in the semiconductor substrate 110, any one may function as a source region, and any one may function as a drain region. The source region and the drain region can be arbitrarily changed according to wiring lines connected to the respective source or drain regions 111.

The gate insulating film 121 is configured by using an insulating material, and is provided along an internal shape of the opening formed in the semiconductor substrate 110. Specifically, the opening formed in the semiconductor substrate 110 is provided up to a region that is deeper than the source or drain regions 111 in the semiconductor substrate 110, and the gate insulating film 121 is provided along a bottom surface and a side surface of the opening. The gate insulating film 121 may be formed by using an insulating material that is publicly known as a gate insulating film of a field effect transistor. For example, the gate insulating film 121 may be formed by using silicon oxide (SiOₓ), silicon nitride (SiNₓ), or insulating oxynitride such as silicon oxynitride (SiON).

The lower electrode 120 is configured by using a conductive material, and is provided on the gate insulating film 121 to fill the opening formed in the semiconductor substrate 110. For example, the lower electrode 120 may be formed by using polysilicon or the like, or may be formed by using metal, alloy, or a metal compound. Note that the lower electrode 120 is not electrically connected to another wiring line, and is provided in an independent potential state (what is called a floating state).

The ferroelectric film 131 is configured by using a ferroelectric material, and is provided along an internal shape of an opening provided in the lower electrode 120. Specifically, the opening provided in the lower electrode 120 is provided inside the lower electrode 120, and the ferroelectric film 131 is provided along a bottom surface and a side surface of the opening. Note that the opening provided in the lower electrode 120 may be provided to expose the gate insulating film 121.

The ferroelectric film 131 is formed by using a ferroelectric material that is voluntarily polarized and has a direction of residual polarization that can be controlled by an external electric field. Specifically, the ferroelectric film 131 is formed by using a ferroelectric material including hafnium (Hf), zirconium (Zr), silicon (Si), or oxygen (O). For example, the ferroelectric film 131 may be formed by using a ferroelectric material having a perovskite structure, such as lead zirconate titanate (Pb(Zr, Ti)O₃: PZT) or strontium bismuth tantalate (SrBi₂Ta₂O₉: SBT). Furthermore, the ferroelectric film 131 may be a ferroelectric film obtained by performing heat treatment or the like on a film including a high dielectric material such as HfOₓ, ZrOₓ, or HfZrOₓ to modify the film, or may be a ferroelectric film obtained by introducing atoms such as lanthanum (La), silicon (Si), or gadolinium (Gd) into the film including the high dielectric material described above to modify the film. Moreover, the ferroelectric film 131 may be formed to have a single layer, or may be formed to have a plurality of layers. For example, the ferroelectric film 131 may be a single-layer film including a ferroelectric material such as HfOₓ.

The upper electrode 130 is configured by using a conductive material, and is provided on the ferroelectric film 131 to fill the opening formed in the lower electrode 120. For example, the upper electrode 130 may be formed by using metal such as titanium (Ti) or tungsten (W), or a metal compound such as titanium nitride (TiN) or tantalum nitride (TaN).

The conductor electrode 140 is configured by using a conductive material, and is provided on the upper electrode 130. However, the conductor electrode 140 is provided in a size that does not come into contact with the lower electrode 120 such that the lower electrode 120 is in a floating state. The conductor electrode 140 functions as a connecting terminal of the semiconductor storage device 100, for example, by being electrically connected to another wiring line in a layer that is located above the semiconductor substrate 110. The conductor electrode 140 may be formed by using, for example, a metal material such as copper (Cu) or aluminum (Al).

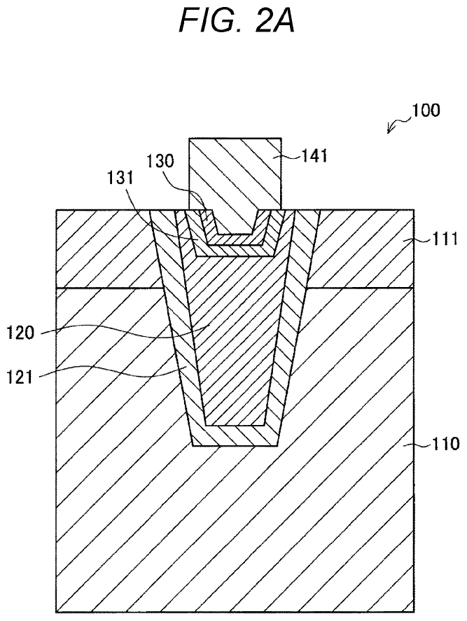

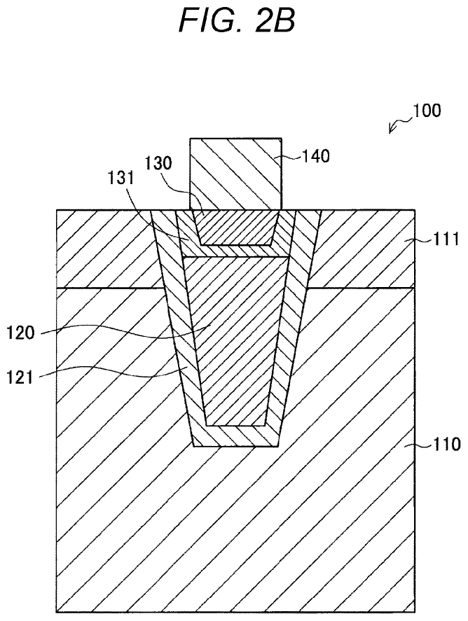

Note that the semiconductor storage device 100 may have the structure illustrated in FIG. 2A or FIG. 2B. FIGS. 2A and 2B are longitudinal sectional views each schematically illustrating a structure in a variation of the semiconductor storage device 100.

As illustrated in FIG. 2A, a conductor electrode 141 may be provided on the upper electrode 130 to fill the opening provided in the lower electrode 120. Stated another way, the conductor electrode 141 may be provided in such a way that a portion of the conductor electrode 141 is embedded into the semiconductor substrate 110, and not being provided on a surface of the semiconductor substrate 110. A material or the like that configures the conductor electrode 141 is substantially similar to a material or the like of the conductor electrode 140, and description is omitted here.

Furthermore, as illustrated in FIG. 2B, in the semiconductor storage device 100, an opening provided in the lower electrode 120 may be provided to expose the gate insulating film 121, and the ferroelectric film 131 may be provided to come into contact with the gate insulating film 121. For example, the opening provided in the lower electrode 120 may cause the lower electrode 120 to be recessed from a surface of the semiconductor substrate 110, and the ferroelectric film 131 and the upper electrode 130 may be formed in a recessed region of the lower electrode 120. In the semiconductor storage device 100 illustrated in FIG. 2B, the lower electrode 120 that is in a floating state is not exposed on the surface of the semiconductor substrate 110. Therefore, the conductor electrode 141 can be formed to have an arbitrary size without consideration of a possibility of coming into contact with the lower electrode 120.

In the semiconductor storage device 100 according to the present embodiment, by applying a voltage V between the upper electrode 130 and the source or drain region 111, a voltage is applied to the ferroelectric film 131 of the ferroelectric capacitor and the gate insulating film 121 of the field effect transistor. At this time, voltages that are inversely proportional to a ratio of the capacitance Cf of the ferroelectric capacitor and the gate capacitance Ci of the field effect transistor are respectively applied to the ferroelectric film 131 and the gate insulating film 121. Specifically, a distributed voltage Vf (=V(Ci/(Ci+Cf)) is applied to the ferroelectric film 131, and a distributed voltage Vi (=V(Cf/(Ci+Cf)) is applied to the gate insulating film 121.

Here, the distributed voltage Vf applied to the ferroelectric film 131 depends on a coupling ratio (Ci/(Ci+Cf)) of the capacitance Cf of the ferroelectric capacitor and the gate capacitance Ci of the field effect transistor.

However, in general, the permittivity of the ferroelectric film 131 that has been formed by using a ferroelectric material is higher than the permittivity of the gate insulating film 121 that has been formed by using an insulating material. Therefore, in a case where the area of the ferroelectric film 131 is the same as the area of the gate insulating film 121, the capacitance Cf of the ferroelectric capacitor is greater than the gate capacitance Ci of the field effect transistor. In such a case, a large portion of the voltage V applied between the upper electrode 130 and the source or drain region 111 is distributed to the gate insulating film 121 of the field effect transistor.

In the semiconductor storage device 100 according to the present embodiment, the field effect transistor and the ferroelectric capacitor are provided inside the opening provided in the semiconductor substrate 110, and the ferroelectric capacitor is provided on the field effect transistor. In such a case, in the field effect transistor, a channel is three-dimensionally formed over a plurality of surfaces. By doing this, in the field effect transistor, an effective length of a channel can be increased in comparison with a planar type field effect transistor formed on a semiconductor substrate having the same area (a field effect transistor in which a gate insulating film and a gate electrode have been stacked in parallel on a semiconductor substrate), and therefore gate capacitance Ci can be increased.

Accordingly, the semiconductor storage device 100 according to the present embodiment can increase the gate capacitance Ci of the field effect transistor without an increase in the size of a unit cell, and can increase a distributed voltage to be applied to the ferroelectric film 131. Therefore, the semiconductor storage device 100 can apply a sufficient voltage to the ferroelectric film 131, and thus the stability of operations to write and erase information can be improved.

(1.2. Design Example)

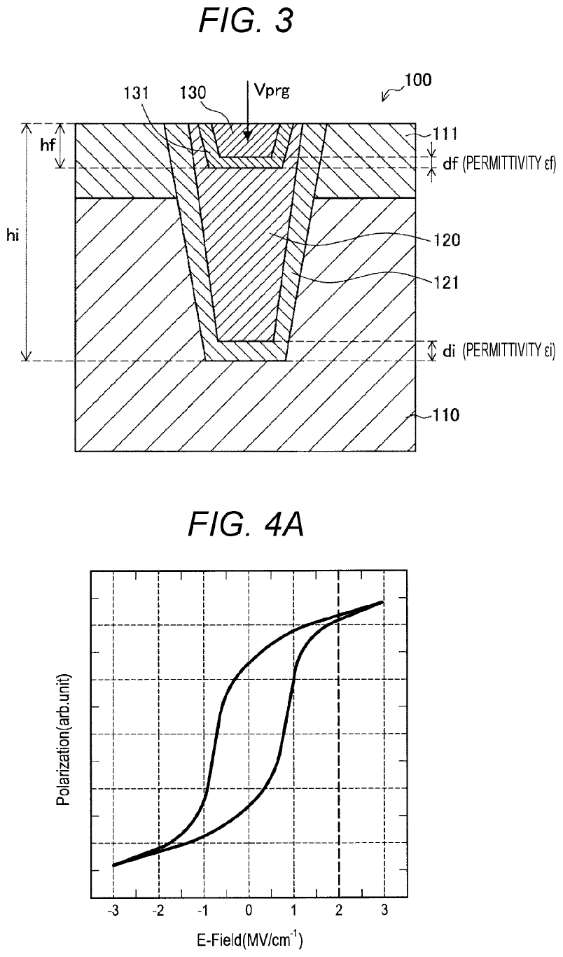

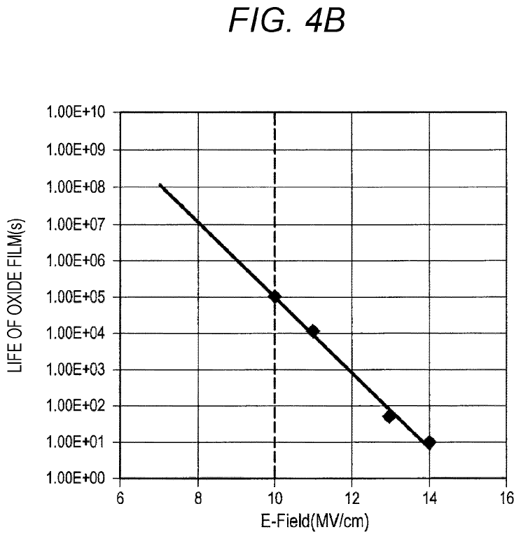

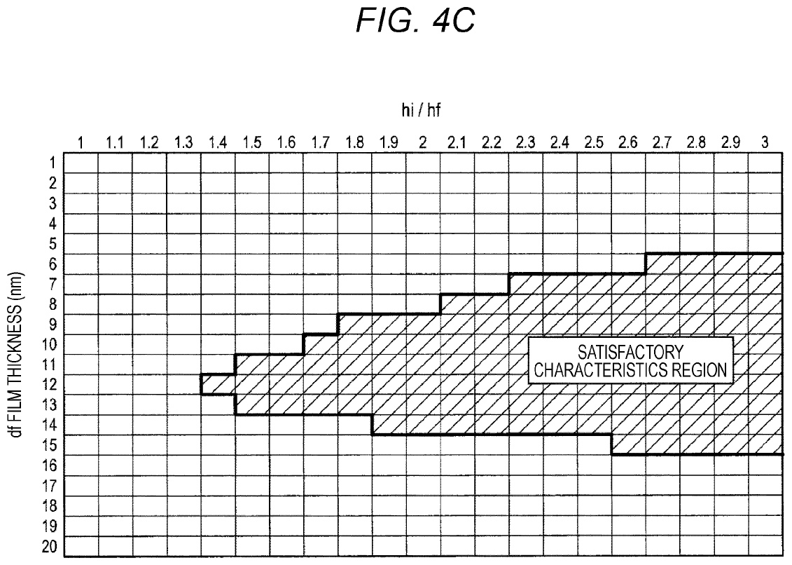

Next, a specific design example of the semiconductor storage device 100 according to the present embodiment is described with reference to FIGS. 3 to 4C. FIG. 3 is a longitudinal sectional view that defines the dimensions of each configuration of the semiconductor storage device 100 illustrated in FIG. 1, and FIGS. 4A to 4C are graphs illustrating a range that causes the semiconductor storage device 100 according to the present embodiment to have satisfactory characteristics.

As illustrated in FIG. 3, it is assumed that the depth of the opening formed in the semiconductor substrate 110 is hi, the depth of the opening formed in the lower electrode 120 is hf, the film thickness of the gate insulating film 121 is di, and the film thickness of the ferroelectric film 131 is df. Furthermore, it is assumed that the relative permittivity of the gate insulating film 121 is εi and the relative permittivity of the ferroelectric film 131 is εf. In such a case, by controlling the dimensions of each configuration to satisfy the conditions described below, the characteristics of the semiconductor storage device 100 can be made more satisfactory.

Specifically, in a case where a voltage Vprg is applied to the upper electrode 130, the voltage Vf applied to the ferroelectric film 131 and the voltage Vi applied to the gate insulating film 121 are expressed by the formulae described below.

$$Vf = Vprg \text{/} ( 1 + Cf \text{/} Ci ) = Vprg \text{/} ( 1 + ( ɛ f \cdot hf \cdot di ) \text{/} ( ɛ i \cdot hi \cdot df ) )$$

$$Vi = Vprg - Vf$$

Accordingly, an electric field Ef that is generated in the ferroelectric film 131 and an electric field Ei that is generated in the gate insulating film 121 are expressed by the formulae described below.

Ef=Vprg/df·(1+(εf·hf·di)/(εi·hi·df))

Ei=di·(Vprg−Vf)

Here, in order to obtain sufficient residual polarization in the ferroelectric film 131, it is desirable that Ef>2 MV/cm. Furthermore, in order to not generate dielectric breakdown in the gate insulating film 121, it is desirable that Ei<10 MV/cm.

Specifically, in a case where the ferroelectric film 131 is formed by using a ferroelectric material including Hf, an amount of residual polarization of the ferroelectric film 131 with respect to an electric field is, for example, as illustrated in the graph of FIG. 4A. FIG. 4A illustrates a result of polarization-electric field measurement that has been obtained from a ferroelectric capacitor in which the area of the ferroelectric film 131 is 7500 μm², the film thickness of the ferroelectric film 131 is 12 nm, and the ferroelectric film 131 is formed by using HfOₓ. When the graph illustrated in FIG. 4A is referred to, it is apparent that it is preferable that an electric field to be generated in the ferroelectric film 131 be greater than 2 MV/cm, in order to sufficiently saturate a hysteresis loop of polarization of the ferroelectric film 131 and obtain sufficiently great residual polarization.

Furthermore, in a case where the gate insulating film 121 includes a silicon oxide film, the length of the life of the gate insulating film 121 with respect to an electric field is as illustrated in the graph of FIG. 4B. FIG. 4B illustrates a result of measuring dielectric breakdown of a field effect transistor in which the area of the gate insulating film 121 is 5000 μm², the film thickness of the gate insulating film 121 is 12 μm, and the gate insulating film 121 includes a silicon oxide film. When the graph illustrated in FIG. 4B is referred to, it is apparent that it is preferable that an electric field to be generated in the gate insulating film 121 be smaller than 10 MV/cm, in order to achieve a life of the gate insulating film 121 of 1.00E+05 or more, which is a practically sufficient life.

Accordingly, by appropriately designing hf, hi, df, and di in such a way that Ef and Ei described above satisfy a preferable range, the characteristics of the semiconductor storage device 100 can be made satisfactory.

For example, in a case where the ferroelectric film 131 is formed by using a ferroelectric material including Hf, εf is about 20, and in a case where the gate insulating film 121 is formed by using a silicon oxide film, εi about 3.9. Here, in a case where it is assumed that the film thickness of the gate insulating film 121 is 1 nm and Vprg is 3.5 V, a suitable ratio of hf and hi and a suitable film thickness df of the ferroelectric film 131 fall within the range illustrated in FIG. 4C. FIG. 4C is a graph illustrating a combination of a ratio of hf/hi and the film thickness df of the ferroelectric film 131. By employing a ratio of hf and hi and the film thickness df of the ferroelectric film 131 in a region painted in black in FIG. 4C, the semiconductor storage device 100 can have more suitable characteristics.

(1.3. Manufacturing Method)

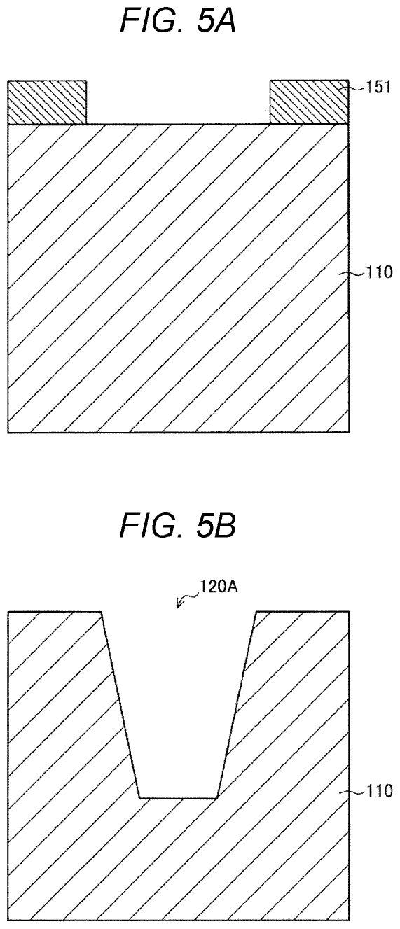

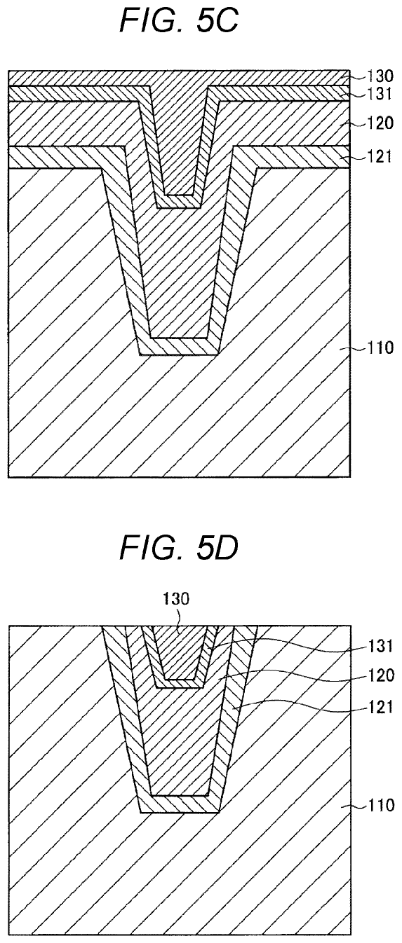

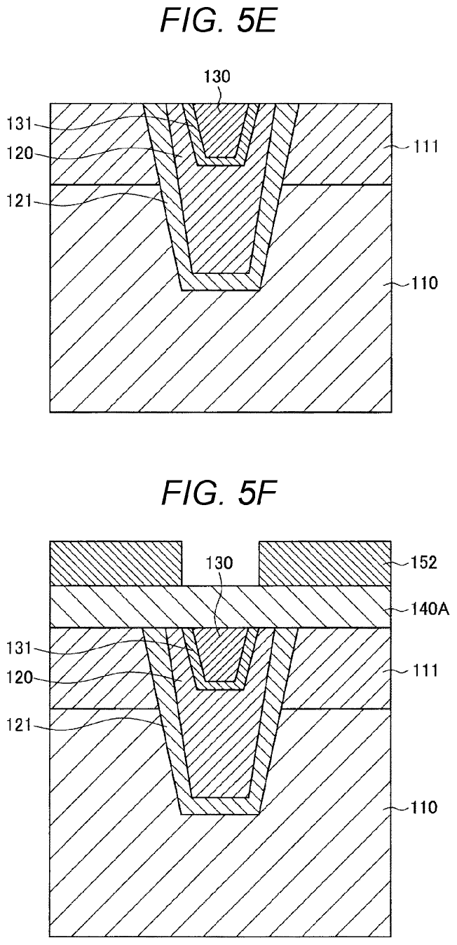

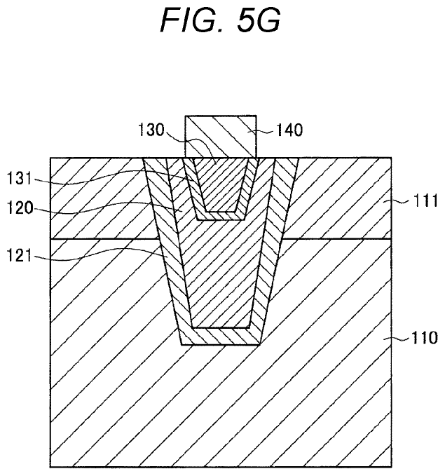

Next, a manufacturing method of the semiconductor storage device 100 according to the present embodiment is described with reference to FIGS. 5A to 5G. FIGS. 5A to 5G are schematic longitudinal sectional views each illustrating one process of the manufacturing method of the semiconductor storage device 100 according to the present embodiment.

First, as illustrated in FIG. 5A, patterning is performed to form a mask 151, on the semiconductor substrate 110 formed by using silicon, for forming an opening 120A in the semiconductor substrate 110. For example, the mask 151 may be a simple substance of photoresist, or may be a laminate of a hard mask such as an oxide film or a nitride film and photoresist.

Next, as illustrated in FIG. 5B, by etching the semiconductor substrate 110 by using the mask 151, the opening 120A that corresponds to the pattern of the mask 151 is formed in the semiconductor substrate 110. Note that ion-implantation may be performed such that first conductive type (for example, p-type) channel implantation that adjusts a threshold voltage of the field effect transistor is formed in the semiconductor substrate 110 after which the opening 120A has been formed.

Next, as illustrated in FIG. 5C, the gate insulating film 121, the lower electrode 120, the ferroelectric film 131, and the upper electrode 130 are sequentially formed on the semiconductor substrate 110. Specifically, the gate insulating film 121, the lower electrode 120, the ferroelectric film 131, and the upper electrode 130 are sequentially formed on the semiconductor substrate 110 along an outer shape of the semiconductor substrate 110 that has been provided with the opening 120A, and therefore the opening 120A provided in the semiconductor substrate 110 is filled. The film thickness of each of the gate insulating film 121, the lower electrode 120, the ferroelectric film 131, and the upper electrode 130 can be adjusted to have a value within the range described above that causes the semiconductor storage device 100 to have satisfactory characteristics. As materials that configure the gate insulating film 121, the lower electrode 120, the ferroelectric film 131, and the upper electrode 130, the materials described above can be appropriately used.

Next, as illustrated in FIG. 5D, chemical mechanical polishing (CMP) or the like is performed to polish a side of a surface on which the opening 120A of the semiconductor substrate 110 has been formed until the surface of the semiconductor substrate 110 is exposed. Note that polishing such as CMP may also be continued after the surface of the semiconductor substrate 110 has been exposed. Furthermore, in FIG. 5D, the height of the surface of the semiconductor substrate 110 after polishing matches the heights of the surfaces of the gate insulating film 121, the lower electrode 120, the ferroelectric film 131, and the upper electrode 130. However, for example, a center of the upper electrode 130 may be recessed.

Next, as illustrated in FIG. 5E, ion-implantation is performed to introduce a second conductive type impurity (for example, an n-type impurity) into the semiconductor substrate 110 on both sides of the opening 120A, and therefore the source or drain regions 111 are formed. Note that the second conductive type impurity may be introduced into the semiconductor substrate 110 via a resist mask or the like, or may not be introduced via the resist mask or the like. Note that a process of forming the source or drain regions 111 may be performed before or immediately after the opening 120A is formed in the semiconductor substrate 110.

Next, as illustrated in FIG. 5F, after a conductor electrode layer 140A has been formed on the semiconductor substrate 110 by using sputtering or the like, a mask 152 is provided on the conductor electrode layer 140A. As a material that configures the conductor electrode layer 140A, the material described above can be appropriately used.

Thereafter, as illustrated in FIG. 5G, patterning is performed on the conductor electrode layer 140A by using the mask 152, and therefore a conductor electrode 140 with a size that does not come into contact with the lower electrode 120 is formed on the upper electrode 130.

By performing the processes described above, the semiconductor storage device 100 according to the present embodiment can be manufactured.

(1.4. Application Examples)

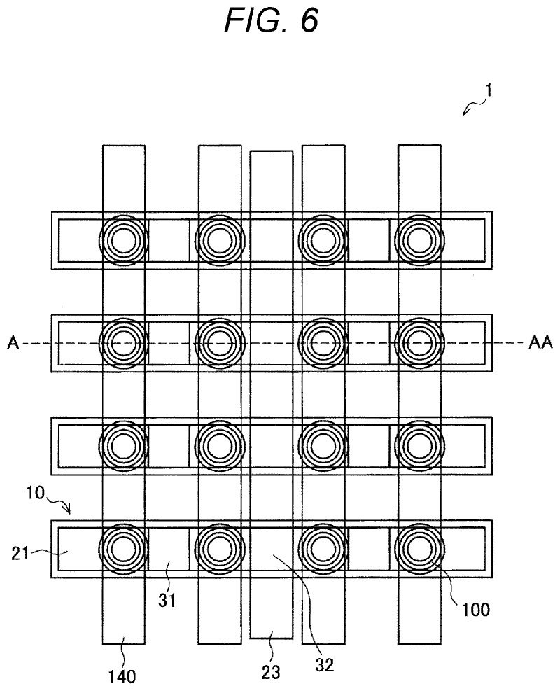

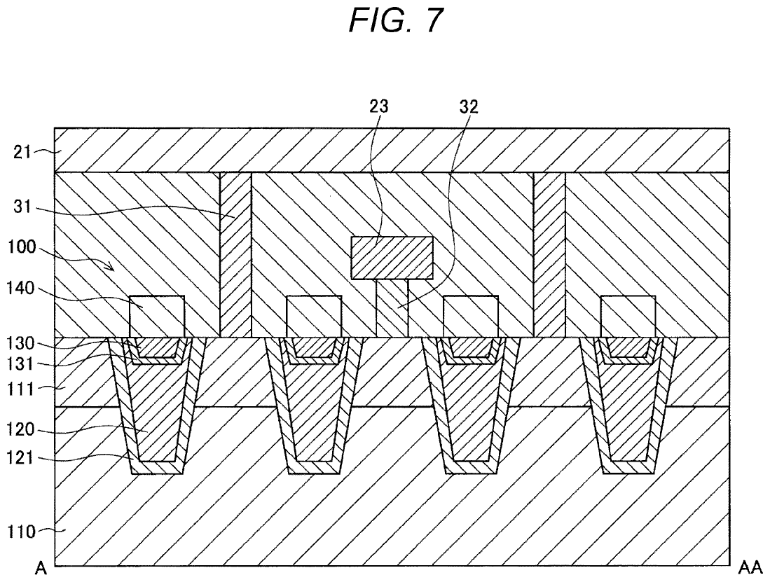

Next, application examples of the semiconductor storage device 100 according to the present embodiment are described with reference to FIGS. 6 to 9. FIG. 6 is a plan view schematically illustrating a planar configuration of a semiconductor device 1 in which a plurality of semiconductor storage devices 100 according to the present embodiment is arranged in a matrix shape, and FIG. 7 is a longitudinal sectional view schematically illustrating a section that is taken along line A-AA of the semiconductor device 1 illustrated in FIG. 6.

As illustrated in FIGS. 6 and 7, the semiconductor device 1 is a storage device that can store a large amount of information in the plurality of semiconductor storage devices 100 that has been arranged in a matrix shape. Furthermore, the semiconductor device 1 can also be used as a multiplier-accumulator that can perform a multiply-accumulate operation, by using, as synapses, the plurality of semiconductor storage devices 100 that has been arranged in a matrix shape and using a resistance value of a channel of the semiconductor storage device 100 as the weight of the synapse.

In the semiconductor device 1, a wiring line 21 that extends in a first direction (for example, leftward and rightward directions facing FIG. 6) is electrically connected to one of the source or drain regions 111 of the semiconductor storage device 100 via a contact 31. The conductor electrode 140 is provided to extend in a second direction (for example, upward and downward directions facing FIG. 6) that is orthogonal to the first direction. Furthermore, a wiring line 23 is electrically connected to the other of the source or drain regions 111 of the semiconductor storage device 100 via a contact 32. Moreover, the semiconductor storage device 100 is provided in the semiconductor substrate 110 at each intersection of the wiring line 21 and the conductor electrode 140 that are orthogonal to each other. Note that the semiconductor storage devices 100 that are adjacent in the second direction are electrically insulated against each other by an element isolation layer 10 having insulation.

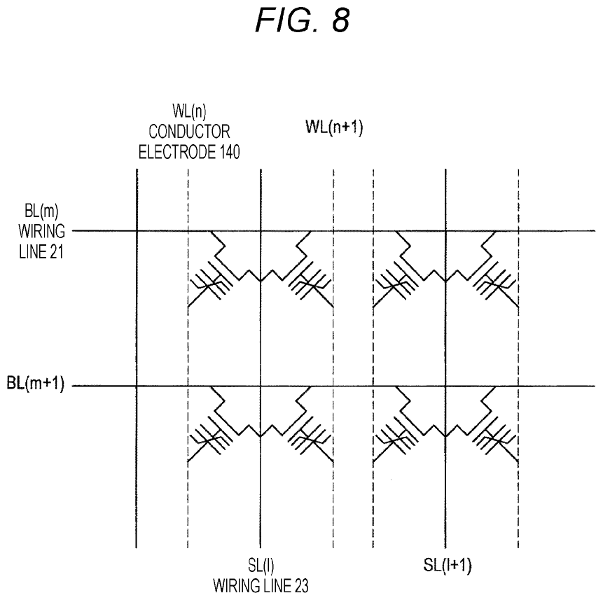

Here, an operation to write or read information in the semiconductor device 1 is described with further reference to FIG. 8. FIG. 8 is an equivalent circuit diagram of the semiconductor device 1 illustrated in FIGS. 6 and 7.

As illustrated in FIG. 8, in a case where information is written, for example, the semiconductor device 1 provides a potential difference between a predetermined wiring line 21 and a predetermined conductor electrode 140 to selectively apply the potential difference to a semiconductor storage device 100 that is present at an intersection of the predetermined wiring line 21 and the predetermined conductor electrode 140. By doing this, the semiconductor device 1 can selectively inverse residual polarization of the ferroelectric film 131 of the semiconductor storage device 100 that is present at the intersection of the wiring line 21 and the conductor electrode 140, and can write information to the semiconductor storage device 100.

On the other hand, in a case where information is read, for example, the semiconductor device 1 applies a voltage to the conductor electrode 140 to cause the field effect transistor of the semiconductor storage device 100 to enter into an ON state, and then measures a current that flows between the wiring line 21 and the wiring line 23 (that is, a current that flows between a source and a drain of the semiconductor storage device 100). By doing this, the semiconductor device 1 can obtain a current value that corresponds to a direction of residual polarization of the ferroelectric film 131 from each of the semiconductor storage devices 100, and therefore the semiconductor device 1 can read information from each of the semiconductor storage devices 100.

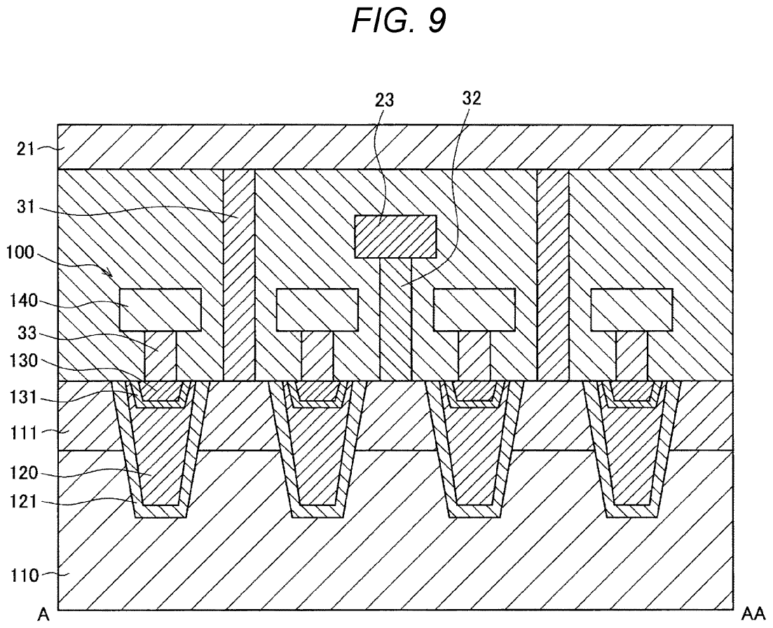

Note that the sectional structure illustrated in FIG. 7 of the semiconductor device 1 may be the sectional structure illustrated in FIG. 9. FIG. 9 is a longitudinal sectional view schematically illustrating a sectional structure in a variation of the semiconductor device 1. As illustrated in FIG. 9, the conductor electrode 140 may be electrically connected to the upper electrode 130 via a contact 33.

The semiconductor storage device 100 according to the first embodiment of the present disclosure has been described in detail above.

### 2. Second Embodiment

(2.1. Structure Examples)

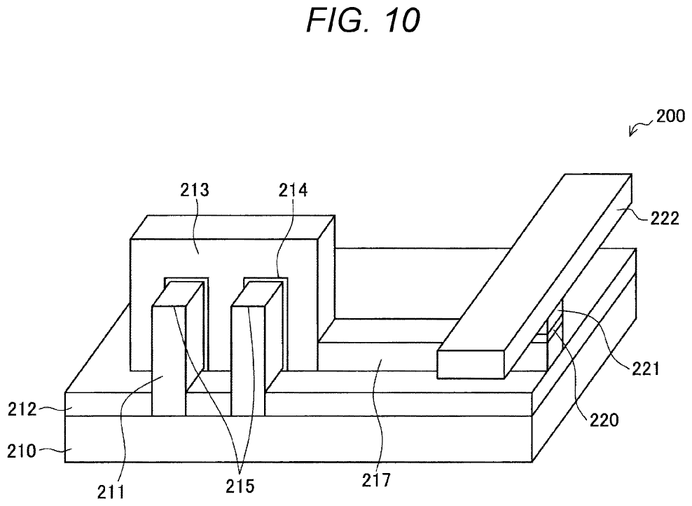

Next, a structure example of a semiconductor storage device according to a second embodiment of the present disclosure is described with reference to FIG. 10. FIG. 10 is a perspective view schematically illustrating a structure example of the semiconductor storage device according to the present embodiment.

As illustrated in FIG. 10, a semiconductor storage device 200 includes a semiconductor substrate 210, an insulating layer 212, a semiconductor layer 211, source or drain regions 215, a gate insulating film 214, a gate electrode 213, a lower electrode 217, a ferroelectric film 220, an upper electrode 221, and a conductor electrode 222.

The semiconductor storage device 200 is an FeRAM that has an MFMIS structure in which a ferroelectric capacitor is connected in series to a gate electrode of a field effect transistor. Specifically, the field effect transistor is a fin-type field effect transistor that includes the semiconductor layer 211, the source or drain regions 215, the gate insulating film 214, and the gate electrode 213. The ferroelectric capacitor includes the lower electrode 217, the ferroelectric film 220, and the upper electrode 221. The lower electrode 120 is electrically connected to the gate electrode 213 of the field effect transistor, and therefore the ferroelectric capacitor is connected in series to a gate of the field effect transistor.

The semiconductor substrate 210 is a substrate that is configured by using a semiconductor material. The semiconductor substrate 210 may be a silicon substrate, or may be a silicon on insulator (SOI) substrate in which an insulating film of SiO₂ or the like is held in the silicon substrate. Alternatively, the semiconductor substrate 210 may be a substrate that includes another elemental semiconductor such as germanium or a substrate that includes a compound semiconductor such as gallium arsenide (GaAs), gallium nitride (GaN), or silicon carbide (SiC). Moreover, the semiconductor substrate 210 may be a substrate in which a semiconductor layer has been stacked on a substrate including quartz, sapphire, resin, metal, or the like.

The insulating layer 212 is configured by using an insulating material, and is provided on the semiconductor substrate 210. The insulating layer 212 electrically insulates respective configurations, e.g., the gate electrode 213, the lower electrode 217, and the like that are provided on the semiconductor substrate 210 against the semiconductor substrate 210. Furthermore, in a case where a plurality of semiconductor layers 211 is provided, the insulating layer 212 electrically insulates the respective semiconductor layers 211 that are protrusively provided on the semiconductor substrate 210 against each other. The insulating layer 212 may be formed, for example, by using silicon oxide (SiOₓ), silicon nitride (SiNₓ), or insulating oxynitride such as silicon oxynitride (SiON).

The semiconductor layer 211 is configured by using a semiconductor material, and is protrusively provided on the semiconductor substrate 210 to pierce the insulating layer 212. Specifically, the semiconductor layer 211 can be protrusively provided on the semiconductor substrate 210 to have a rectangular parallelepiped shape that extends in one direction. For example, the semiconductor layer 211 may have a flat plate shape, and may be protrusively provided on the semiconductor substrate 210 in such a way that a principal surface (a surface having a largest area) of the flat plate shape is perpendicular to the semiconductor substrate 210. Furthermore, in a case where a plurality of semiconductor layers 211 is provided, each of the plurality of semiconductor layers 211 may be protrusively provided on the semiconductor substrate 210 in such a way that extending directions are parallel to each other. For example, the semiconductor layer 211 may be formed by using silicon, may be formed by using another elemental semiconductor such as germanium, or may be formed by using a compound semiconductor such as gallium arsenide (GaAs), gallium nitride (GaN), or silicon carbide (SiC).

The gate insulating film 214 is configured by using an insulating material, and is provided to cover an upper surface and side surfaces of the semiconductor layer 211 in a direction that is orthogonal to an extending direction of the semiconductor layer 211. The gate insulating film 214 may be provided to be sandwiched between the gate electrode 213, which is provided astride the semiconductor layer 211 in the direction that is orthogonal to the extending direction of the semiconductor layer 211, and the semiconductor layer 211. The gate insulating film 214 may be formed by using an insulating material that is publicly known as a gate insulating film of a field effect transistor. For example, the gate insulating film 214 may be formed by using silicon oxide (SiOₓ), silicon nitride (SiNₓ), or insulating oxynitride such as silicon oxynitride (SiON).

The gate electrode 213 is configured by using a conductive material, and is provided astride the semiconductor layer 211 via the gate insulating film 214 in the direction that is orthogonal to the extending direction of the semiconductor layer 211. For example, the gate electrode 213 may be provided on the semiconductor layer 211 to extend in the direction that is orthogonal to the extending direction of the semiconductor layer 211 and intersect with the semiconductor layer 211. Furthermore, in a case where a plurality of semiconductor layers 211 is provided, the gate electrode 213 may be provided, on the plurality of semiconductor layers 211 that is provided to extend in parallel to each other, to extend in a direction that is orthogonal to the extending directions of the semiconductor layers 211, and therefore the gate electrode 213 may be continuously provided astride the plurality of semiconductor layers 211. For example, the gate electrode 213 may be formed by using polysilicon or the like, or may be formed by using metal, alloy, or a metal compound.

Note that the gate insulating film 214 and the gate electrode 213 are provided roughly in the center of the semiconductor layer 211 in such a way that the semiconductor layer 211 protrudes from both sides of the gate electrode 213. By doing this, the source or drain regions 215 described later can be formed in the semiconductor layer 211 that protrudes on both sides of the gate electrode 213.

The source or drain regions 215 are second conductive type regions (for example, n-type regions) that have been formed in the semiconductor layer 211. Specifically, the source or drain regions 215 are provided in regions that protrude on both sides of the gate electrode 213 in the semiconductor layer 211. For example, the source or drain regions 215 can be provided by introducing a second conductive type impurity (for example, an n-type impurity such as phosphorus or arsenic) into regions of the semiconductor layer 211 that protrude from both sides of the gate electrode 213.

Note that, from among the source or drain regions 215 that are provided in the semiconductor layer 211, any one may function as a source region, and any one may function as a drain region. The source region and the drain region can be arbitrarily changed according to wiring lines connected to the respective source or drain regions 215.

The lower electrode 217 is configured by using a conductive material, and is provided on the insulating layer 212 to be electrically connected to the gate electrode 213. Specifically, the lower electrode 217 may be provided to be electrically connected to the gate electrode 213 and extend in the direction that is orthogonal to the extending direction of the semiconductor layer 211. For example, the lower electrode 217 may be formed by using polysilicon or the like, or may be formed by using metal, alloy, or a metal compound. Note that a place where the lower electrode 217 is formed is not particularly limited, if the lower electrode 217 is electrically connected to the gate electrode 213 and is in an independent potential state (what is called a floating state).

The ferroelectric film 220 is configured by using a ferroelectric material, and is provided on the lower electrode 217. Specifically, the ferroelectric film 220 is provided on the lower electrode 217 that extends on the insulating layer 212.

The ferroelectric film 220 is formed by using a ferroelectric material that is voluntarily polarized and has a direction of residual polarization that can be controlled by an external electric field. The ferroelectric film 220 is formed by using a ferroelectric material including hafnium (Hf), zirconium (Zr), silicon (Si), or oxygen (O). For example, the ferroelectric film 220 may be formed by using a ferroelectric material having a perovskite structure, such as lead zirconate titanate (Pb(Zr, Ti)O₃: PZT) or strontium bismuth tantalate (SrBi₂Ta₂O₉: SBT). Furthermore, the ferroelectric film 220 may be a ferroelectric film obtained by performing heat treatment or the like on a film including a high dielectric material such as HfOₓ, ZrOₓ, or HfZrOₓ to modify the film, or may be a ferroelectric film obtained by introducing atoms such as lanthanum (La), silicon (Si), or gadolinium (Gd) into the film including the high dielectric material described above to modify the film. Moreover, the ferroelectric film 220 may be formed to have a single layer, or may be formed to have a plurality of layers. For example, the ferroelectric film 220 may be a single-layer film including a ferroelectric material such as HfOₓ.

The upper electrode 221 is configured by using a conductive material, and is provided on the ferroelectric film 220. For example, the upper electrode 221 may be formed by using metal such as titanium (Ti) or tungsten (W), or a metal compound such as titanium nitride (TiN) or tantalum nitride (TaN).

The conductor electrode 222 is configured by using a conductive material, and is provided on the upper electrode 221. Specifically, the conductor electrode 222 may be provided on the upper electrode 221 to extend in the extending direction of the semiconductor layer 211. Stated another way, the conductor electrode 222 and the lower electrode 217 may be provided to be orthogonal to each other, and the ferroelectric film 220 and the upper electrode 221 may be provided to be sandwiched between the conductor electrode 222 and the lower electrode 217 at an intersection of the conductor electrode 222 and the lower electrode 217. For example, the conductor electrode 222 may be formed by using, for example, a metal material such as copper (Cu) or aluminum (Al).

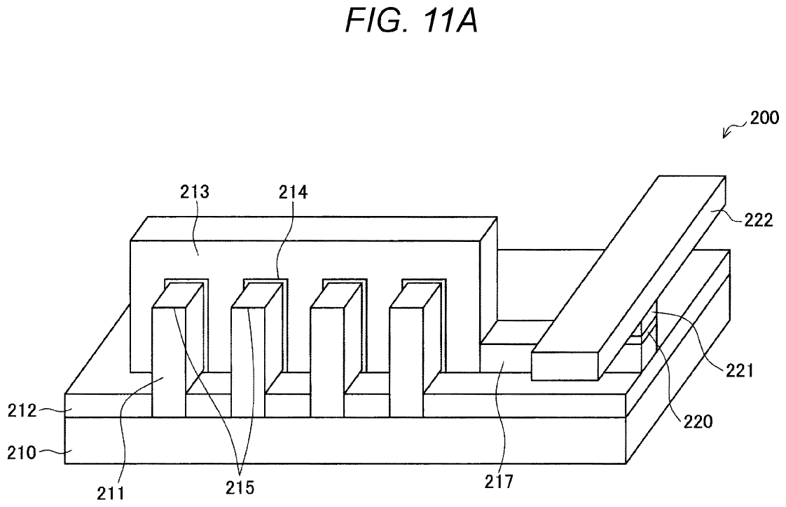

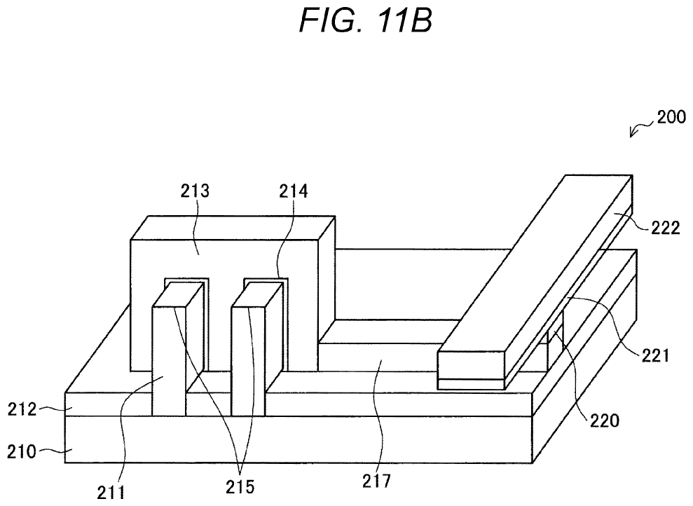

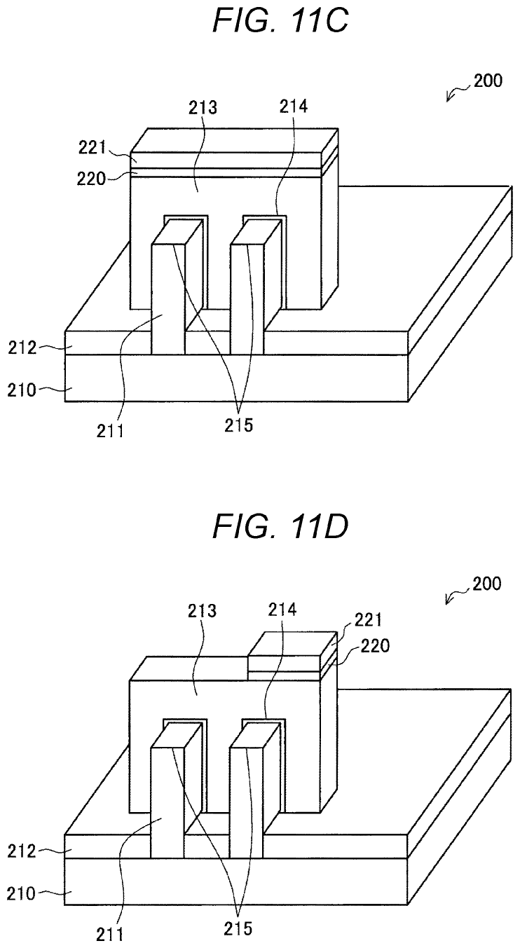

Note that the semiconductor storage device 200 may have the structures illustrated in FIGS. 11A to 11D. FIGS. 11A to 11D are longitudinal sectional views each schematically illustrating a structure in a variation of the semiconductor storage device 200.

As illustrated in FIG. 11A, a plurality of semiconductor layers 211 may be provided. Note that an upper limit of the number of semiconductor layers 211 is not particularly limited. In such a case, each of the plurality of semiconductor layers 211 may be protrusively provided on the semiconductor substrate 210 in such a way that extending directions are parallel to each other. Furthermore, the gate electrode 213 may be provided, on the plurality of semiconductor layers 211 that are provided to extend in parallel to each other, to extend in a direction that is orthogonal to the extending directions of the semiconductor layers 211, and therefore the gate electrode 213 may be continuously provided astride the plurality of semiconductor layers 211. The gate insulating film 214 may be provided to be sandwiched between the semiconductor layer 211 and the gate electrode 213.

Furthermore, as illustrated in FIG. 11B, the upper electrode 221 may be provided in a wiring shape that extends in the extending direction of the semiconductor layer 211 similarly to the conductor electrode 222. In such a case, the upper electrode 221 may be formed in the same shape as the shape of the conductor electrode 222, and wiring may be formed by the conductor electrode 222 and the upper electrode 221.

Furthermore, as illustrated in FIGS. 11C and 11D, the ferroelectric film 220 and the upper electrode 221 may be provided to be sequentially stacked on a gate electrode 216. The area in which the ferroelectric film 220 and the upper electrode 221 are stacked may be the entirety of an upper surface of the gate electrode 216, as illustrated in FIG. 11C, or may be a part of the upper surface of the gate electrode 216, as illustrated in FIG. 11D. Furthermore, a conductor electrode 222 that is not illustrated may be stacked on the upper electrode 221. In such a case, the semiconductor storage device 200 can further reduce a planar area per unit cell. Note that, in the semiconductor storage devices 200 illustrated in FIGS. 11C and 11D, the ferroelectric film 220 is directly stacked on the gate electrode 216, and therefore the lower electrode 217 may be omitted.

In the semiconductor storage device 200 according to the present embodiment, the field effect transistor is provided as what is called a fin-type transistor. In such a case, in the field effect transistor, a channel is three-dimensionally formed over a plurality of surfaces, side surfaces and an upper surface, of the semiconductor layer 211. By doing this, in the field effect transistor, the area of the channel can be increased in comparison with a planar type field effect transistor that has been formed on a semiconductor substrate having the same area (a field effect transistor in which a gate insulating film and a gate electrode have been stacked in parallel on a semiconductor substrate), and therefore gate capacitance Ci can be increased.

Accordingly, the semiconductor storage device 200 according to the present disclosure can increase the gate capacitance Ci of the field effect transistor without an increase in the size of a unit cell, and can increase a distributed voltage to be applied to the ferroelectric film 220. Therefore, the semiconductor storage device 200 can apply a sufficient voltage to the ferroelectric film 220, and thus the stability of operations to write and erase information can be improved.

(2.2. Design Example)

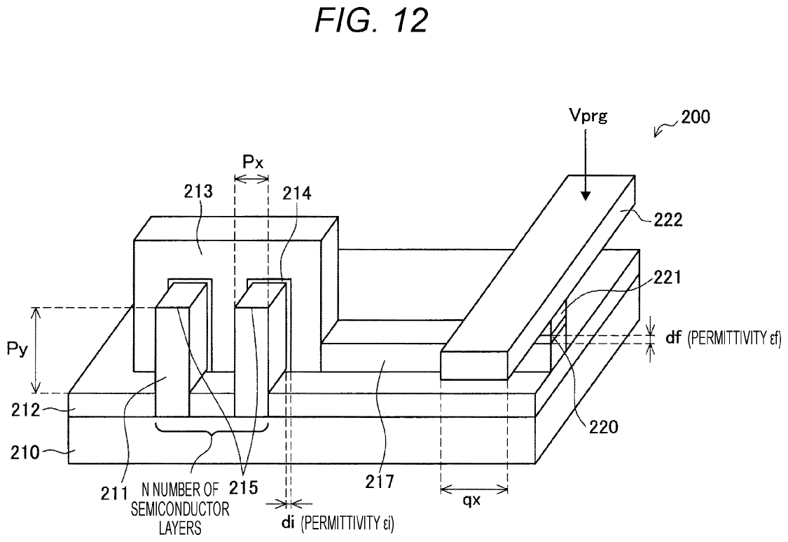

Next, a specific design example of the semiconductor storage device 200 according to the present embodiment is described with reference to FIG. 12. FIG. 12 is a perspective view that defines the dimensions of each configuration of the semiconductor storage device 200 illustrated in FIG. 10.

As illustrated in FIG. 12, it is assumed that a width in a direction that is orthogonal to an extending direction of the semiconductor layer 211 is px, a height from a surface of the insulating layer 212 of the semiconductor layer 211 is py, and the number of semiconductor layers 211 is N. It is assumed that a width in the direction that is orthogonal to the extending direction of the semiconductor layer 211 of the conductor electrode 222 is qx, and the gate electrode 213 and the lower electrode 217 have the same width in the extending direction of the semiconductor layer 211. It is assumed that the film thickness of the gate insulating film 214 is di, the film thickness of the ferroelectric film 220 is df, the relative permittivity of the gate insulating film 214 is εi, and the relative permittivity of the ferroelectric film 220 is εf. In such a case, by controlling the dimensions of each configuration to satisfy the conditions described below, the characteristics of the semiconductor storage device 200 can be made more satisfactory.

Specifically, in a case where a voltage Vprg is applied to the conductor electrode 222, an electric field

Ef that is generated in the ferroelectric film 220 and an electric field Ei that is generated in the gate insulating film 214 are expressed by the formulae described below.

Ef=Vprg/df·(1+(εf·gx·di)/(εi·(px+2py)·N·df))

Ei=di·(Vprg−Vf)

Here, as described above, in order to obtain sufficient residual polarization in the ferroelectric film 220, it is desirable that Ef>2 MV/cm. Furthermore, in order to not generate dielectric breakdown in the gate insulating film 214, it is desirable that Ei<10 MV/cm.

Accordingly, by appropriately designing px, py, N, qx, df, and di in such a way that Ef and Ei described above satisfy a preferable range, the characteristics of the semiconductor storage device 200 can be made satisfactory.

(2.3. Application Example)

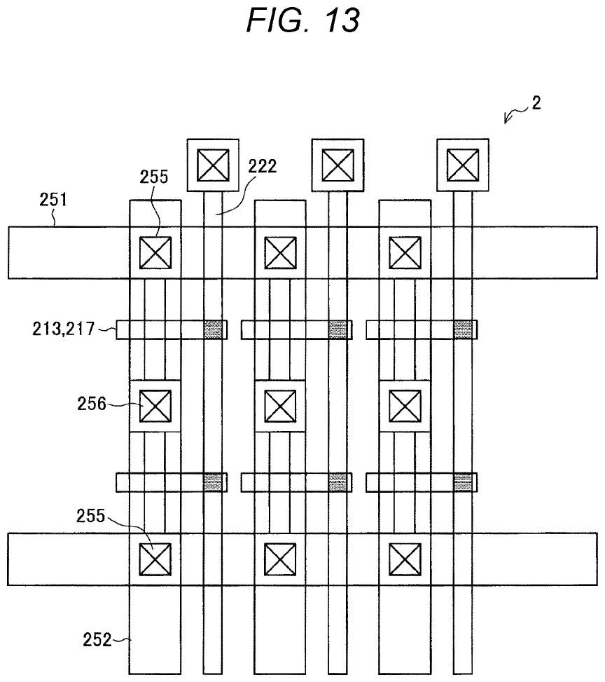

Next, an application example of the semiconductor storage device 200 according to the present embodiment is described with reference to FIG. 13. FIG. 13 is a plan view schematically illustrating a planar configuration of a semiconductor device 2 in which the plurality of semiconductor storage devices 200 according to the present embodiment is arranged in a matrix shape.

As illustrated in FIG. 13, the semiconductor device 2 is a storage device that can store a large amount of information in the plurality of semiconductor storage devices 200 that has been arranged in a matrix shape. Furthermore, the semiconductor device 2 can be used as a multiplier-accumulator that can perform a multiply-accumulate operation, by using, as synapses, the plurality of semiconductor storage devices 200 that has been arranged in a matrix shape and using a resistance value of a channel of the semiconductor storage device 200 as the weight of the synapse.

In the semiconductor device 2, a wiring line 251 that extends in a first direction (for example, leftward and rightward directions facing FIG. 13) is electrically connected to one of the source or drain regions 215 of the semiconductor storage device 200 via a contact 255. A wiring line 252 that extends in a second direction (for example, upward and downward directions facing FIG. 13) that is orthogonal to the first direction is electrically connected to the other of the source or drain regions 111 of the semiconductor storage device 200 via a contact 256. Furthermore, the conductor electrode 222 is provided to extend in the second direction (for example, upward and downward directions facing FIG. 13) that is orthogonal to the first direction. Moreover, a ferroelectric capacitor is provided at an intersection of the conductor electrode 222, and the gate electrode 213 and the lower electrode 217 that are orthogonal to each other.

Here, an operation to write or read information in the semiconductor device 2 is described.

In a case where information is written, for example, the semiconductor device 2 provides a potential difference between a predetermined wiring line 251 and a predetermined conductor electrode 222 to selectively apply the potential difference to a ferroelectric capacitor that is provided at an intersection of the conductor electrode 222, and the gate electrode 213 and the lower electrode 217. By doing this, the semiconductor device 2 can selectively inverse residual polarization of a ferroelectric film 220 of a predetermined ferroelectric capacitor, and can write information to the semiconductor storage device 200.

On the other hand, in a case where information is read, for example, the semiconductor device 2 applies a voltage to the conductor electrode 222 to cause the field effect transistor of the semiconductor storage device 200 to enter into an ON state, and then measures a current that flows between the wiring line 251 and the wiring line 252 (that is, a current that flows between a source and a drain of the semiconductor storage device 200). By doing this, the semiconductor device 2 can obtain a current value that corresponds to a direction of residual polarization of the ferroelectric film 220 from each of the semiconductor storage devices 200, and therefore the semiconductor device 2 can read information from each of the semiconductor storage devices 200.

The semiconductor storage device 200 according to the second embodiment of the present disclosure has been described in detail above.

### 3. Third Embodiment

(3.1. Structure Example)

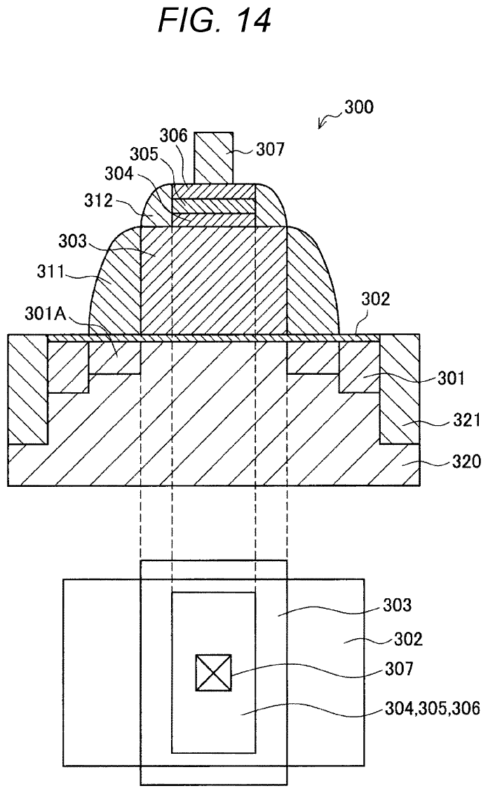

Next, a structure example of a semiconductor storage device according to a third embodiment of the present disclosure is described with reference to FIG. 14. FIG. 14 is a longitudinal sectional view schematically illustrating a structure example of the semiconductor storage device according to the present embodiment.

As illustrated in FIG. 14, a semiconductor storage device 300 includes a semiconductor substrate 320, an element isolation layer 321, source or drain regions 301, an LDD region 301A, a gate insulating film 302, a gate electrode 303, a first side wall 311, a lower electrode 304, a ferroelectric film 305, an upper electrode 306, a second side wall 312, and a conductor electrode 307.

The semiconductor storage device 300 is an FeRAM that has an MFMIS structure in which a ferroelectric capacitor is connected in series on a gate electrode of a field effect transistor. Specifically, the field effect transistor includes the semiconductor substrate 320, the source or drain regions 301, the LDD region 301A, the gate insulating film 302, and the gate electrode 303, and the ferroelectric capacitor includes the lower electrode 304, the ferroelectric film 305, and the upper electrode 306. The ferroelectric capacitor is connected in series to a gate of the field effect transistor by the lower electrode 304.

The semiconductor substrate 320 is a substrate that is configured by using a semiconductor material. A first conductive type impurity (for example, a p-type impurity such as boron or aluminum) has been introduced into the semiconductor substrate 320 in a region where the semiconductor storage device 300 is formed. The semiconductor substrate 320 may be a silicon substrate, or may be a silicon on insulator (SOI) substrate in which an insulating film of SiO₂ or the like is held in the silicon substrate. Alternatively, the semiconductor substrate 320 may be a substrate that includes another elemental semiconductor such as germanium, or a substrate that includes a compound semiconductor such as gallium arsenide (GaAs), gallium nitride (GaN), or silicon carbide (SiC). Moreover, the semiconductor substrate 320 may be a substrate in which a semiconductor layer has been stacked on a substrate including quartz, sapphire, resin, metal, or the like.

The element isolation layer 321 is configured by using an insulating material, and electrically insulates respective semiconductor storage devices 300 provided in the semiconductor substrate 320 against each other. For example, the element isolation layer 321 may be formed, for example, by using silicon oxide (SiOₓ), silicon nitride (SiNₓ), or insulating oxynitride such as silicon oxynitride (SiON).

Specifically, the element isolation layer 321 may be formed by performing etching or the like to remove a part of the semiconductor substrate 320 in a predetermined region by using shallow trench isolation (STI) and filling an opening formed by etching or the like with silicon oxide (SiOₓ). Furthermore, the element isolation layer 321 may be formed by performing thermal oxidation on the semiconductor substrate 320 in a predetermined region by using local oxidation of silicon (LOCOS).

The source or drain regions 301 are second conductive type regions (for example, n-type regions) that have been formed in the semiconductor substrate 320. Specifically, the source or drain regions 301 are provided by introducing a second conductive type impurity (for example, an n-type impurity such as phosphorus or arsenic) into the semiconductor substrate 320 on both sides with respect to the gate electrode 213.

Note that, in the semiconductor substrate 320 between the source or drain region 301 and the gate electrode 303, the lightly-doped drain (LDD) region 301A may be formed that is of a second conductive type (for example, an n-type), which is the same as the type of the source or drain region 301, and has the density of a conductive type impurity that is lower than the density of the source or drain region 301.

Note that, from among the source or drain regions 301 that are provided on both sides with respect to the gate electrode 303, any one may function as a source region, and any one may function as a drain region. The source region and the drain region can be arbitrarily changed according to wiring lines connected to the respective source or drain regions 301.

The gate insulating film 302 is configured by using an insulating material, and is provided on the semiconductor substrate 320. The gate insulating film 302 may be formed by using an insulating material that is publicly known as a gate insulating film of a field effect transistor. For example, the gate insulating film 302 may be formed by using silicon oxide (SiOₓ), silicon nitride (SiNₓ), or insulating oxynitride such as silicon oxynitride (SiON).

The gate electrode 303 is configured by using a conductive material, and is provided on the gate insulating film 302. For example, the gate electrode 303 may be provided on the semiconductor layer 211 to extend in a direction that is orthogonal to an extending direction of the semiconductor layer 211 and intersect with the semiconductor layer 211. For example, the gate electrode 303 may be formed by using polysilicon or the like, or may be formed by using metal, alloy, or a metal compound.

The first side wall 311 is configured by using an insulating material, and is provided as a side wall on a side surface of the gate electrode 303. Specifically, the first side wall 311 can be formed by uniformly forming an insulating film in a region including the gate electrode 303 and performing vertical anisotropic etching on the insulating film. For example, the first side wall 311 may be formed by using silicon oxide (SiOₓ), silicon nitride (SiNₓ), or insulating oxynitride such as silicon oxynitride (SiON) to have a single layer or a plurality of layers.

When introducing the second conductive type impurity into the semiconductor substrate 320, the first side wall 311 shields the second conductive type impurity to control a positional relationship between the gate electrode 303 and the source or drain region 301 in a self-aligning manner. By using the first side wall 311, the introduction of the second conductive type impurity into the semiconductor substrate 320 can be controlled stepwise, and therefore the LDD region 301A can be formed between the source or drain region 301 and the gate electrode 303 in a self-aligning manner.

The lower electrode 304 is configured by using a conductive material, and is provided on the gate electrode 303. For example, the lower electrode 304 may be formed by using polysilicon or the like, or may be formed by using metal, alloy, or a metal compound.

The ferroelectric film 305 is configured by using a ferroelectric material, and is provided on the lower electrode 304. The ferroelectric film 305 is formed by using a ferroelectric material that is voluntarily polarized and has a direction of residual polarization that can be controlled by an external electric field. Specifically, the ferroelectric film 305 is formed by using a ferroelectric material including hafnium (Hf), zirconium (Zr), silicon (Si), or oxygen (O). For example, the ferroelectric film 305 may be formed by using a ferroelectric material having a perovskite structure, such as lead zirconate titanate (Pb(Zr, Ti)O₃: PZT) or strontium bismuth tantalate (SrBi₂Ta₂O₉: SBT). Furthermore, the ferroelectric film 305 may be a ferroelectric film obtained by performing heat treatment or the like on a film including a high dielectric material such as HfOₓ, ZrOₓ, or HfZrOₓ to modify the film, or may be a ferroelectric film obtained by introducing atoms such as lanthanum (La), silicon (Si), or gadolinium (Gd) into the film including the high dielectric material described above to modify the film. Moreover, the ferroelectric film 305 may be formed to have a single layer, or may be formed to have a plurality of layers. For example, the ferroelectric film 305 may be a single-layer film including a ferroelectric material such as HfOₓ.

The upper electrode 306 is configured by using a conductive material, and is provided on the ferroelectric film 305. For example, the upper electrode 306 may be formed by using metal such as titanium (Ti) or tungsten (W), or a metal compound such as titanium nitride (TiN) or tantalum nitride (TaN).

Here, the lower electrode 304, the ferroelectric film 305, and the upper electrode 306 are provided in the same planar shape, and the second side wall 312 is provided on a side surface of a laminate of the lower electrode 304, the ferroelectric film 305, and the upper electrode 306.

The second side wall 312 is configured by using an insulating material, and is provided as a side wall on the side surface of the laminate of the lower electrode 304, the ferroelectric film 305, and the upper electrode 306. Specifically, the second side wall 312 can be formed by uniformly forming an insulating film on the laminate of the lower electrode 304, the ferroelectric film 305, and the upper electrode 306 and performing vertical anisotropic etching on the insulating film. For example, the second side wall 312 may be formed by using silicon oxide (SiOₓ), silicon nitride (SiNₓ), or insulating oxynitride such as silicon oxynitride (SiON) to have a single layer or a plurality of layers.

Here, a planar area that is occupied by the laminate of the lower electrode 304, the ferroelectric film 305, and the upper electrode 306 and the second side wall 312 can be roughly equal to the planar area of an upper surface of the gate electrode 303. As described later, in the semiconductor storage device 300, first, etching is performed to form the laminate of the lower electrode 304, the ferroelectric film 305, and the upper electrode 306, and the second side wall 312, and thereafter, etching is performed by using, as a mask, the laminate and the second side wall 312, and therefore the gate electrode 303 is formed. By doing this, in the semiconductor storage device 300, the laminate of the lower electrode 304, the ferroelectric film 305, and the upper electrode 306, the second side wall 312, the gate electrode 303, and the first side wall 311 can be formed in a self-aligning manner.

The conductor electrode 307 is configured by using a conductive material, and is provided on the upper electrode 306. The conductor electrode 307 functions as a connecting terminal of the semiconductor storage device 300, for example, by being electrically connected to another wiring line that is not illustrated. The conductor electrode 307 may be formed by using, for example, a metal material such as titanium (Ti), tungsten (W), copper (Cu), or aluminum (Al).

In the semiconductor storage device 300 according to the present embodiment, the field effect transistor is provided as a planar type transistor, and the ferroelectric capacitor is provided together with the second side wall 312 on the gate electrode of the field effect transistor. In such a case, the area of the ferroelectric film 305 of the ferroelectric capacitor is slightly smaller than the area of the gate insulating film 302 of the field effect transistor by the width of the second side wall 312. By doing this, in the semiconductor storage device 300, the gate capacitance Ci of the field effect transistor can be larger than the capacitance Cf of the ferroelectric capacitor.

Accordingly, the semiconductor storage device 300 according to the present embodiment can increase the gate capacitance Ci of the field effect transistor without an increase in the size of a unit cell, and can increase a distributed voltage to be applied to the ferroelectric film 305. Therefore, the semiconductor storage device 300 can apply a sufficient voltage to the ferroelectric film 305, and thus the stability of operations to write and erase information can be improved.

(3.2. Design Example)

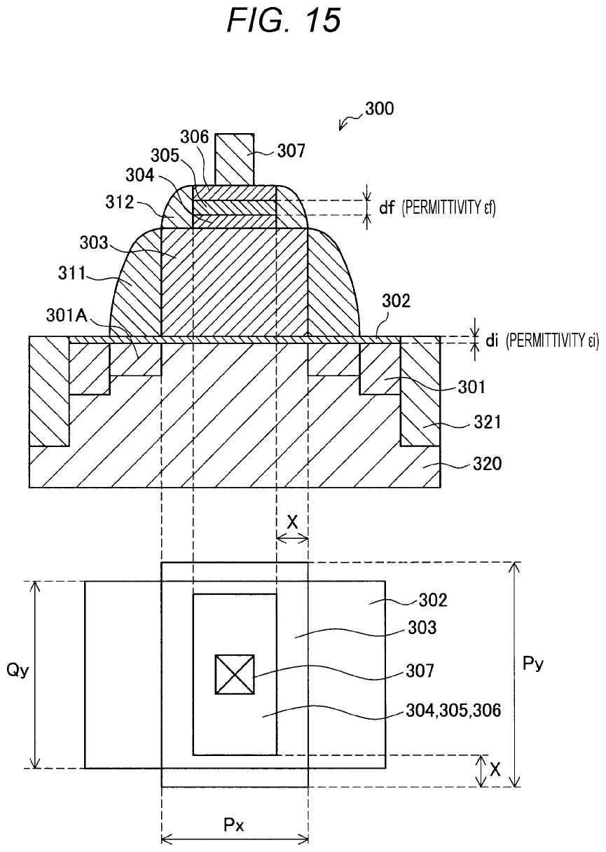

Next, a specific design example of the semiconductor storage device 300 according to the present embodiment is described with reference to FIG. 15. FIG. 15 is a longitudinal sectional view that defines the dimensions of each configuration of the semiconductor storage device 300 illustrated in FIG. 14.

As illustrated in FIG. 15, it is assumed that the width of the gate electrode 303 in a direction in which the source or drain regions 301 are provided (also referred to as a channel direction) is Px and the length of the gate electrode 303 in a direction that is orthogonal to the channel direction is Py. It is assumed that the length of the source or drain region 301 in the direction that is orthogonal to the channel direction is Qy and the width of the second side wall 312 is X. Furthermore, it is assumed that the film thickness of the gate insulating film 302 is di, the film thickness of the ferroelectric film 305 is df, the relative permittivity of the gate insulating film 302 is εi, and the relative permittivity of the ferroelectric film 305 is εf. In such a case, by controlling the dimensions of each configuration to satisfy the conditions described below, the characteristics of the semiconductor storage device 300 can be made more satisfactory.

Specifically, in a case where a voltage Vprg is applied to the conductor electrode 307, an electric field Ef that is generated in the ferroelectric film 305 and an electric field Ei that is generated in the gate insulating film 302 are expressed by the formulae described below.

Ef=Vprg/df·(1+(εf·di)/(εi·df)·(Px−2X)·(Qy−2X)/(Px·Py))

Ei=di·(Vprg−Vf)

Here, as described above, in order to obtain sufficient residual polarization in the ferroelectric film 305, it is desirable that Ef>2 MV/cm. Furthermore, in order to not generate dielectric breakdown in the gate insulating film 302, it is desirable that Ei<10 MV/cm.

Accordingly, by appropriately designing Px, Py, Qy, X, df, and di in such a way that Ef and Ei described above satisfy a preferable range, the characteristics of the semiconductor storage device 300 can be made satisfactory.

(3.3. Manufacturing Method)

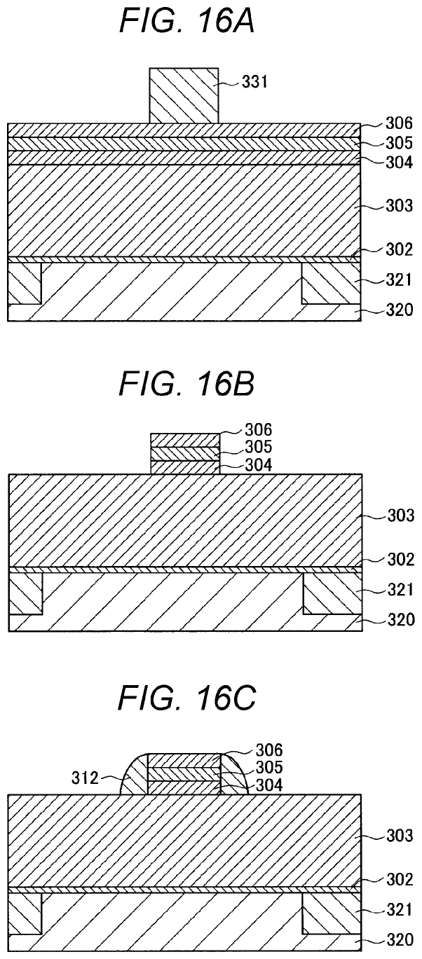

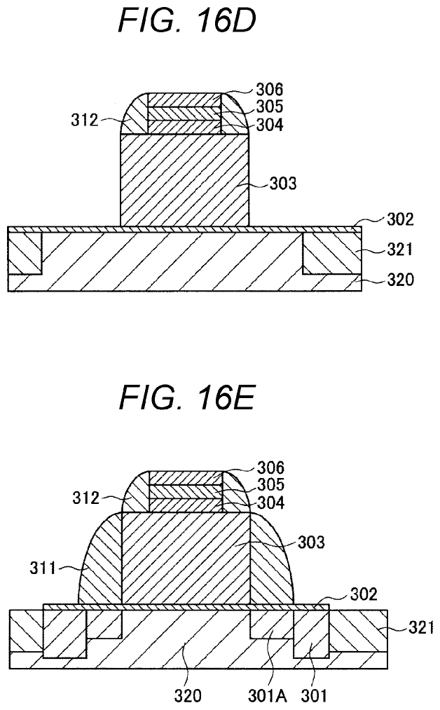

Next, a manufacturing method of the semiconductor storage device 300 according to the present embodiment is described with reference to FIGS. 16A to 16E. FIGS. 16A to 16E are schematic longitudinal sectional views each illustrating one process of the manufacturing method of the semiconductor storage device 300 according to the present embodiment.

First, as illustrated in FIG. 16A, the gate insulating film 302, the gate electrode 303, the lower electrode 304, the ferroelectric film 305, and the upper electrode 306 are uniformly formed on the semiconductor substrate 320 in which the element isolation layer 321 has been formed. Moreover, patterning is performed to form a mask 331, on the upper electrode 306, for forming a ferroelectric capacitor. For example, the mask 331 may be a simple substance of photoresist, or may be a laminate of a hard mask such as an oxide film or a nitride film and photoresist.

Next, as illustrated in FIG. 16B, the lower electrode 304, the ferroelectric film 305, and the upper electrode 306 are simultaneously etched by using the mask 331, and therefore a ferroelectric capacitor that has a size that corresponds to the pattern of the mask 331 (that is, the laminate of the lower electrode 304, the ferroelectric film 305, and the upper electrode 306) is formed.

Next, as illustrated in FIG. 16C, an insulating film is uniformly formed on the laminate of the lower electrode 304, the ferroelectric film 305, and the upper electrode 306, and then, etching-back is performed on the entire surface. Therefore, the second side wall 312 is formed.

Next, as illustrated in FIG. 16D, the gate electrode 303 is etched by using, as a mask, the laminate of the lower electrode 304, the ferroelectric film 305, and the upper electrode 306, and the second side wall 312. By doing this, a mask for performing patterning to form the gate electrode 303 does not need to be separately provided, and therefore a manufacturing cost of the semiconductor storage device 300 can be reduced.

Thereafter, as illustrated in FIG. 16E, ion-implantation is performed to introduce a second conductive type impurity (for example, an n-type impurity) into the semiconductor substrate 320, and therefore the source or drain regions 301 are formed. Note that, as illustrated in FIG. 16E, by forming the first side wall 311, the LDD region 301A may be formed between the gate electrode 303 and the source or drain region 301 in a self-aligning manner.

By performing the processes described above, the semiconductor storage device 300 according to the present embodiment can be manufactured.

(3.4. Variations)

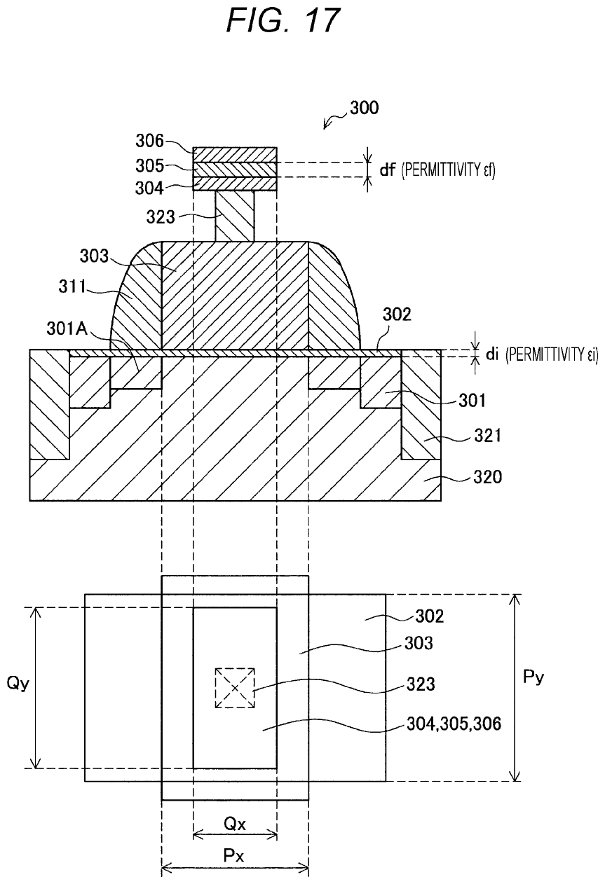

Moreover, variations of the semiconductor storage device 300 according to the present embodiment are described with reference to FIGS. 17 to 19. FIGS. 17 to 19 are longitudinal sectional views each schematically illustrating a structure in a variation of the semiconductor storage device 300.

As illustrated in FIG. 17, the ferroelectric capacitor that includes the lower electrode 304, the ferroelectric film 305, and the upper electrode 306 may be connected in series to the gate electrode 303 of the field effect transistor via a conductor electrode 323. The conductor electrode 323 may be formed by using, for example, a metal material such as titanium (Ti), tungsten (W), copper (Cu), or aluminum (Al), similarly to the conductor electrode 307 described above.

In the structure illustrated in FIG. 17 of the semiconductor storage device 300, by controlling the dimensions of each configuration to satisfy the conditions described below, the characteristics of the semiconductor storage device 300 can be made more satisfactory.

Specifically, it is assumed that the width of the gate electrode 303 in a direction in which the source or drain regions 301 are provided (also referred to as a channel direction) is Px and the length of the source or drain region 301 is Py. It is assumed that the width of the ferroelectric capacitor (that is, the laminate of the lower electrode 304, the ferroelectric film 305, and the upper electrode 306) in the channel direction is Qx and the length of the ferroelectric capacitor in a direction that is orthogonal to the channel direction is Qy. Furthermore, it is assumed that the film thickness of the gate insulating film 302 is di, the film thickness of the ferroelectric film 305 is df, the relative permittivity of the gate insulating film 302 is εi, and the relative permittivity of the ferroelectric film 305 is εf.

In such a case and in a case where a voltage Vprg is applied to the upper electrode 306, an electric field Ef that is generated in the ferroelectric film 305 and an electric field Ei that is generated in the gate insulating film 302 are expressed by the formulae described below.

Ef=Vprg/df·(1+(εf·di)/(εi·df)·(Qx·Qy)/(Px·Py))

Ei=di·(Vprg−Vf)

Here, as described above, in order to obtain sufficient residual polarization in the ferroelectric film 305, it is desirable that Ef>2 MV/cm. Furthermore, in order to not generate dielectric breakdown in the gate insulating film 302, it is desirable that Ei<10 MV/cm.

Accordingly, by appropriately designing Px, Py, Qy, Qx, df, and di in such a way that Ef and Ei described above satisfy a preferable range, the characteristics of the semiconductor storage device 300 can be made satisfactory.

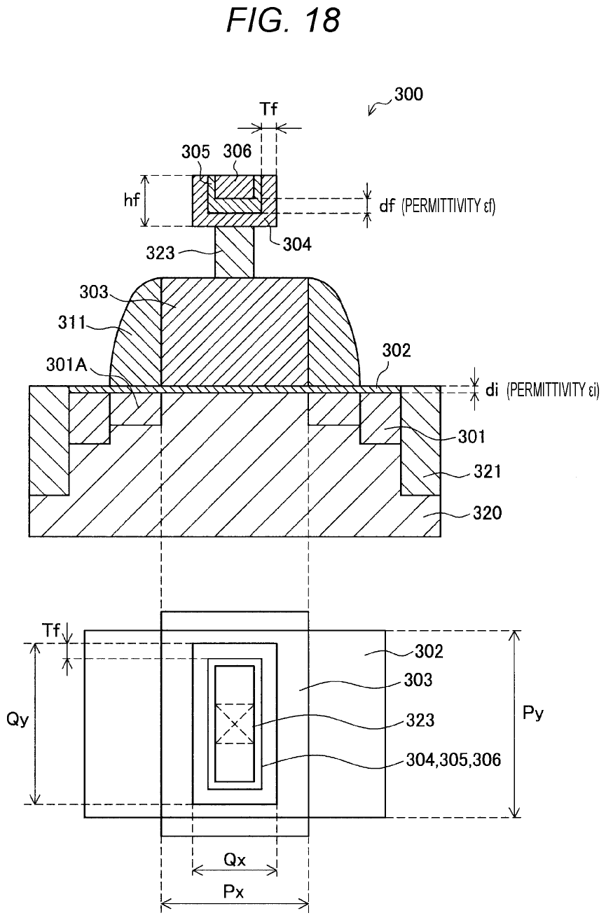

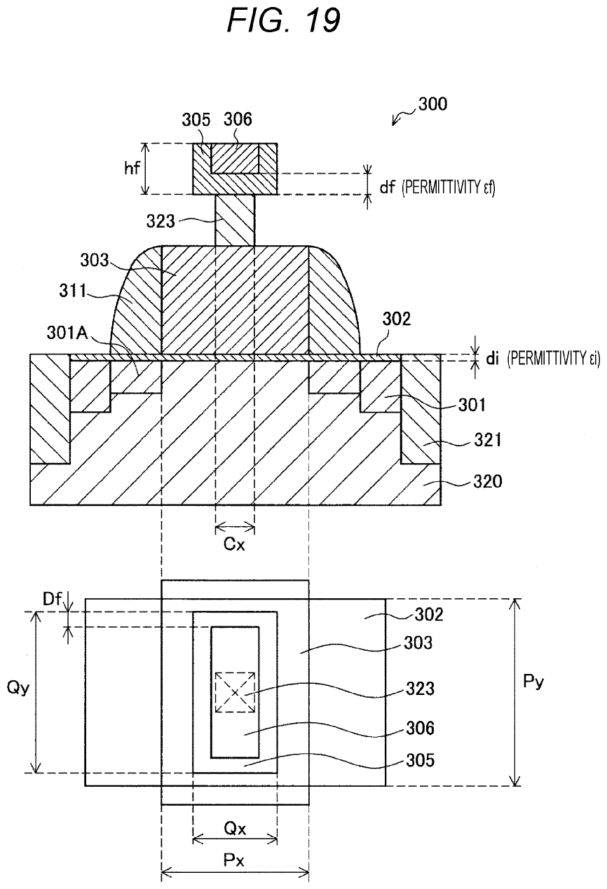

Furthermore, as illustrated in FIG. 18, the ferroelectric capacitor may have a structure in which the ferroelectric film 305 and the upper electrode 306 have been embedded into the lower electrode 304 by using a damascene process, rather than the laminate of the lower electrode 304, the ferroelectric film 305, and the upper electrode 306. The structure illustrated in FIG. 18 of the semiconductor storage device 300 is different from the structure illustrated in FIG. 17 of the semiconductor storage device 300 in the structure of the ferroelectric capacitor.

In the structure illustrated in FIG. 18 of the semiconductor storage device 300, by controlling the dimensions of each configuration to satisfy the conditions described below, the characteristics of the semiconductor storage device 300 can be made more satisfactory.

Specifically, it is assumed that the width of the gate electrode 303 in a direction in which the source or drain regions 301 are provided (also referred to as a channel direction) is Px and the length of the source or drain region 301 is Py. It is assumed that the width of the ferroelectric capacitor in the channel direction is Qx and the length of the ferroelectric capacitor in a direction that is orthogonal to the channel direction is Qy. Furthermore, it is assumed that the film thickness of the gate insulating film 302 is di, the film thickness of the ferroelectric film 305 is df, the relative permittivity of the gate insulating film 302 is εi, and the relative permittivity of the ferroelectric film 305 is εf. Moreover, it is assumed that the height of the lower electrode 304 (that is, the height of the ferroelectric capacitor) is hf and the thickness of the lower electrode 304 is Tf.

In such a case and in a case where a voltage Vprg is applied to the upper electrode 306, an electric field Ef that is generated in the ferroelectric film 305 and an electric field Ei that is generated in the gate insulating film 302 are expressed by the formulae described below.

Ef=Vprg/df·(1+(εf·di)/(εi·df)·Sf/Si)

Ei=di·(Vprg−Vf)

where

Sf=2(hf−Tf−df)·(Qx+Qy−2Tf−2df)+(Qx−2df−2hf)·(Qy−2df−2hf)

Si=Px·Py

Here, as described above, in order to obtain sufficient residual polarization in the ferroelectric film 305, it is desirable that Ef>2 MV/cm. Furthermore, in order to not generate dielectric breakdown in the gate insulating film 302, it is desirable that Ei<10 MV/cm.

Accordingly, by appropriately designing Px, Py, Qy, Qx, Tf, hf, df, and di in such a way that Ef and Ei described above satisfy a preferable range, the characteristics of the semiconductor storage device 300 can be made satisfactory.

Moreover, as illustrated in FIG. 19, the lower electrode 304 may be omitted from the semiconductor storage device 300. The structure illustrated in FIG. 19 of the semiconductor storage device 300 is different from the structure illustrated in FIG. 18 of the semiconductor storage device 300 in that the ferroelectric capacitor includes the conductor electrode 323, the ferroelectric film 305, and the upper electrode 306.

In the structure illustrated in FIG. 19 of the semiconductor storage device 300, by controlling the dimensions of each configuration to satisfy the conditions described below, the characteristics of the semiconductor storage device 300 can be made more satisfactory.

Specifically, it is assumed that the width of the gate electrode 303 in a direction in which the source or drain regions 301 are provided (also referred to as a channel direction) is Px and the length of the source or drain region 301 is Py. It is assumed that the width of the ferroelectric capacitor in the channel direction is Qx and the length of the ferroelectric capacitor in a direction that is orthogonal to the channel direction is Qy. Furthermore, it is assumed that the film thickness of the gate insulating film 302 is di, the film thickness of the ferroelectric film 305 is df, the relative permittivity of the gate insulating film 302 is εi, and the relative permittivity of the ferroelectric film 305 is εf. Moreover, it is assumed that the height of the ferroelectric film 305 (that is, the height of the ferroelectric capacitor) is hf and the width of the conductor electrode 323 is Cx.

In such a case and in a case where a voltage Vprg is applied to the upper electrode 306, an electric field

Ef that is generated in the ferroelectric film 305 and an electric field Ei that is generated in the gate insulating film 302 are expressed by the formulae described below.

Ef=Vprg/df·(1+(εf·di)·(εi·df)·Sf/Si)

Ei=di·(Vprg−Vf)

where

Sf=2(hf−df)·(Qx+Qy−2df)+Cx·Cx

Si=Px·Py

Here, as described above, in order to obtain sufficient residual polarization in the ferroelectric film 305, it is desirable that Ef>2 MV/cm. Furthermore, in order to not generate dielectric breakdown in the gate insulating film 302, it is desirable that Ei<10 MV/cm.

Accordingly, by appropriately designing Px, Py, Qy, Qx, hf, Cx, df, and di in such a way that Ef and Ei described above satisfy a preferable range, the characteristics of the semiconductor storage device 300 can be made satisfactory.

Note that, in FIGS. 17 to 19, the planar shape of the conductor electrode 323 is roughly a square, but the planar shape of the conductor electrode 323 may be any of a rectangle, a circle, or an ellipse.

The semiconductor storage device 300 according to the third embodiment of the present disclosure has been described in detail above. The semiconductor storage device 300 according to the third embodiment of the present disclosure can be applied to a storage device that can store a large amount of information, by arranging the semiconductor storage devices 300 in a matrix shape, similarly to the semiconductor storage devices 100 and 200. Furthermore, the semiconductor storage device 300 can be applied to a multiplier-accumulator that can perform a multiply-accumulate operation, by using the semiconductor storage device 300 as a synapse.

Preferred embodiments of the present disclosure have been described in detail above with reference to the attached drawings, but the technical scope of the present disclosure is not limited to the examples described above. It is obvious that a person with ordinary skill in the technical field of the present disclosure could conceive a variety of variations or modifications without departing from a technical idea described in the claims, and it should be understood that the variations or modifications fall under the technical scope of the present disclosure.

Furthermore, effects described herein are only exemplary or illustrative, and are not restrictive.

Stated another way, a technology according to the present disclosure can exhibit other effects that would be obvious to those skilled in the art from the description provided herein in addition to the effects described above or instead of the effects described above.

Note that the configuration described below also falls under the technical scope of the present disclosure.

(1)

A semiconductor storage device including:

a transistor; and

a ferroelectric capacitor that is formed by sandwiching a ferroelectric material between a pair of conductive materials, one of the pair of conductive materials being electrically connected to a gate electrode of the transistor,

in which a channel of the transistor is three-dimensionally formed over a plurality of surfaces.

(2)

The semiconductor storage device according to (1) described above, in which an electric field applied to the ferroelectric material of the ferroelectric capacitor is greater than 2 MV/cm.

(3)

The semiconductor storage device according to (1) or (2) described above, in which an electric field applied to a gate insulating film of the transistor is smaller than 10 MV/m.

(4)

The semiconductor storage device according to any one of (1) to (3) described above, in which the transistor includes a semiconductor substrate, the gate insulating film, and the gate electrode, the gate insulating film being provided along an internal shape of an opening that has been formed in the semiconductor substrate, the gate electrode being provided on the gate insulating film to fill the opening of the semiconductor substrate, and

the ferroelectric capacitor includes a ferroelectric film and an upper electrode, the ferroelectric film being provided along an internal shape of an opening that has been formed in the gate electrode, the upper electrode being provided on the gate electrode to fill the opening of the gate electrode.

(5)

The semiconductor storage device according to (4) described above, in which the semiconductor substrate is of a first conductive type, and

a source or drain region of a second conductive type is provided on a side of a surface on which the opening of the semiconductor substrate is provided, the second conductive type being different from the first conductive type.

(6)

The semiconductor storage device according to (5) described above, in which the opening of the semiconductor substrate is provided up to a region that is deeper than the source or drain region.

(7)

The semiconductor storage device according to any one of (1) to (3) described above, in which the transistor includes a semiconductor layer, the gate insulating film, and the gate electrode, the semiconductor layer being protrusively provided on a substrate to extend in one direction, the gate insulating film being provided astride the semiconductor layer to cover an upper surface and side surfaces of the semiconductor layer in a direction that is orthogonal to an extending direction of the semiconductor layer, the gate electrode being provided astride the semiconductor layer via the gate insulating film.

(8)

The semiconductor storage device according to (7) described above, in which the ferroelectric capacitor includes one of the pair of conductive materials that has been stacked on the gate electrode, the ferroelectric material that has been stacked on the one of the pair of conductive materials, and another of the pair of conductive materials that has been stacked on the ferroelectric material.

(9)

The semiconductor storage device according to (8) described above, in which a plurality of the semiconductor layers is provided to be parallel to each other, and

the gate electrode is continuously provided over the plurality of the semiconductor layers.

(10)

A multiplier-accumulator including:

a transistor; and

a ferroelectric capacitor that is formed by sandwiching a ferroelectric material between a pair of conductive materials, one of the pair of conductive materials being electrically connected to a gate electrode of the transistor,

in which a channel of the transistor is three-dimensionally formed over a plurality of surfaces.

(11)

A semiconductor storage device including:

a transistor; and

a ferroelectric capacitor that is formed by sandwiching a ferroelectric material between a pair of conductive materials, one of the pair of conductive materials being electrically connected to a gate electrode of the transistor,

in which the pair of conductive materials and the ferroelectric material are stacked to be parallel to an upper surface of the gate electrode, to provide the ferroelectric capacitor on the gate electrode, and

a planar area of the ferroelectric capacitor is smaller than a planar area of the upper surface of the gate electrode.

(12)

The semiconductor storage device according to (11) described above, in which an electric field applied to the ferroelectric material of the ferroelectric capacitor is greater than 2 MV/cm.

(13)

The semiconductor storage device according to (11) or (12) described above, in which an electric field applied to a gate insulating film of the transistor is smaller than 10 MV/m.

(14)

The semiconductor storage device according to or after any of (11) to (13) described above, in which a side wall insulating film is provided on a side surface of the ferroelectric capacitor, and

a planar area that is occupied by the ferroelectric capacitor and the side wall insulating film is roughly equal to the planar area of the upper surface of the gate electrode.

(15)

The semiconductor storage device according to any one of (11) to (13) described above, in which a contact electrode is provided between the ferroelectric capacitor and the gate electrode.

(16)

The semiconductor storage device according to (15) described above, in which the ferroelectric capacitor includes the contact electrode or one of the pair of conductive materials that has been stacked on the contact electrode, the ferroelectric material that has been stacked on the one of the pair of conductive materials, and

another of the pair of conductive materials that fills an opening that has been formed in the ferroelectric material.

(17)

A multiplier-accumulator including:

a transistor; and

a ferroelectric capacitor that is formed by sandwiching a ferroelectric material between a pair of conductive materials, one of the pair of conductive materials being electrically connected to a gate electrode of the transistor,

in which the pair of conductive materials and the ferroelectric material are stacked to be parallel to an upper surface of the gate electrode, to provide the ferroelectric capacitor on the gate electrode, and

a planar area of the ferroelectric capacitor is smaller than a planar area of the upper surface of the gate electrode.

### REFERENCE SIGNS LIST

1 Semiconductor device
10 Element isolation layer
21, 23 Wiring line
31, 32, 33 Contact
100 Semiconductor storage device
110 Semiconductor substrate
111 Source or drain region
120 Lower electrode
121 Gate insulating film
130 Upper electrode
131 Ferroelectric film
140 Conductor electrode

What is claimed is:

1. A semiconductor storage device comprising:
a transistor; and
a ferroelectric capacitor that is formed by sandwiching a ferroelectric material between a pair of conductive materials, one of the pair of conductive materials being electrically connected to a gate electrode of the transistor,
wherein a channel of the transistor is three-dimensionally formed over a plurality of surfaces.

2. The semiconductor storage device according to claim 1, wherein an electric field applied to the ferroelectric material of the ferroelectric capacitor is greater than 2 MV/cm.

3. The semiconductor storage device according to claim 1, wherein an electric field applied to a gate insulating film of the transistor is smaller than 10 MV/m.

4. The semiconductor storage device according to claim 1, wherein the transistor includes a semiconductor substrate, a gate insulating film, and the gate electrode, the gate insulating film being provided along an internal shape of an opening that has been formed in the semiconductor substrate, the gate electrode being provided on the gate insulating film to fill the opening of the semiconductor substrate, and the ferroelectric capacitor includes a ferroelectric film and an upper electrode, the ferroelectric film being provided along an internal shape of an opening that has been formed in the gate electrode, the upper electrode being provided on the gate electrode to fill the opening of the gate electrode.

5. The semiconductor storage device according to claim 4, wherein the semiconductor substrate is of a first conductive type, and
a source or drain region of a second conductive type is provided on a side of a surface on which the opening of the semiconductor substrate is provided, the second conductive type being different from the first conductive type.

6. The semiconductor storage device according to claim 5, wherein the opening of the semiconductor substrate is provided up to a region that is deeper than the source or drain region.

7. The semiconductor storage device according to claim 1, wherein the transistor includes a semiconductor layer, a gate insulating film, and the gate electrode, the semiconductor layer being protrusively provided on a substrate to extend in one direction, the gate insulating film being provided astride the semiconductor layer to cover an upper surface and side surfaces of the semiconductor layer in a direction that is orthogonal to an extending direction of the semiconductor layer, the gate electrode being provided astride the semiconductor layer via the gate insulating film.

8. The semiconductor storage device according to claim 7, wherein the ferroelectric capacitor includes one of the pair of conductive materials that has been stacked on the gate electrode, the ferroelectric material that has been stacked on the one of the pair of conductive materials, and another of the pair of conductive materials that has been stacked on the ferroelectric material.

9. The semiconductor storage device according to claim 8, wherein a plurality of the semiconductor layers is provided to be parallel to each other, and the gate electrode is continuously provided over the plurality of the semiconductor layers.

10. A multiplier-accumulator comprising:
a transistor; and
a ferroelectric capacitor that is formed by sandwiching a ferroelectric material between a pair of conductive materials, one of the pair of conductive materials being electrically connected to a gate electrode of the transistor,
wherein a channel of the transistor is three-dimensionally formed over a plurality of surfaces.

11. A semiconductor storage device comprising:
a transistor; and
a ferroelectric capacitor that is formed by sandwiching a ferroelectric material between a pair of conductive materials, one of the pair of conductive materials being electrically connected to a gate electrode of the transistor,
wherein the pair of conductive materials and the ferroelectric material are stacked to be parallel to an upper surface of the gate electrode, to provide the ferroelectric capacitor on the gate electrode, and
a planar area of the ferroelectric capacitor is smaller than a planar area of the upper surface of the gate electrode.

12. The semiconductor storage device according to claim 11, wherein an electric field applied to the ferroelectric material of the ferroelectric capacitor is greater than 2 MV/cm.

13. The semiconductor storage device according to claim 11, wherein an electric field applied to a gate insulating film of the transistor is smaller than 10 MV/m.

14. The semiconductor storage device according to claim 11, wherein a side wall insulating film is provided on a side surface of the ferroelectric capacitor, and a planar area that is occupied by the ferroelectric capacitor and the side wall insulating film is roughly equal to the planar area of the upper surface of the gate electrode.

15. The semiconductor storage device according to claim 11, wherein a contact electrode is provided between the ferroelectric capacitor and the gate electrode.

16. The semiconductor storage device according to claim 15, wherein the ferroelectric capacitor includes the contact electrode or one of the pair of conductive materials that has been stacked on the contact electrode, the ferroelectric material that has been stacked on the one of the pair of conductive materials, and another of the pair of conductive materials that fills an opening that has been formed in the ferroelectric material.

17. A multiplier-accumulator comprising:
a transistor; and
a ferroelectric capacitor that is formed by sandwiching a ferroelectric material between a pair of conductive materials, one of the pair of conductive materials being electrically connected to a gate electrode of the transistor,
wherein the pair of conductive materials and the ferroelectric material are stacked to be parallel to an upper surface of the gate electrode, to provide the ferroelectric capacitor on the gate electrode, and
a planar area of the ferroelectric capacitor is smaller than a planar area of the upper surface of the gate electrode.
